(19) United States
(12) Patent Application Publication
(10) Pub. No.: US 2025/0287642 A1
(43) Pub. Date: Sep. 11, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Chih-Hao CHANG, Chu-Bei City, Hsin-Chu (TW); Jhon-Jhy LIAW, Zhudong Township, Hsinchu County (TW)

(21) Appl. No.: 18/599,830

(22) Filed: Mar. 8, 2024

(51) Int. Cl. H01L 29/417; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017; H10D 84/017; H10D 84/038; H10D 84/85

(57) ABSTRACT

A semiconductor structure includes a first transistor and a second transistor over the first transistor. The first transistor includes first nanostructures spaced apart from each other in a Z-direction, and first second source/drain features attached to opposite sides of the first nanostructures in an X-direction. The second transistor includes second nanostructures over the first nanostructures and spaced apart from each other in the Z-direction; and third and fourth source/drain features, attached to opposite sides of the second nanostructures in the X-direction and vertically overlapping the first and second source/drain features, respectively. The semiconductor structure further includes a gate structure that is wrapped around the first nanostructures and the second nanostructures. The semiconductor structure further includes a first source/drain contact, extending through the third source/drain feature and partially extending into the first source/drain feature; and a second source/drain contact extending into the first source/drain feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been introduced to improve gate control by increasing gate-channel coupling, reducing off-state current, and reducing short-channel effects (SCEs). As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-Z cross-sectional view of a semiconductor device, in accordance with some embodiments of the present disclosure.

FIG. 1B is an X-Z cross-sectional view of the semiconductor device, in accordance with some embodiments of the present disclosure.

FIG. 2A is a Y-Z cross-sectional view of the semiconductor device, in accordance with some alternative embodiments of the present disclosure.

FIG. 2B is an X-Z cross-sectional view of the semiconductor device, in accordance with some alternative embodiments of the present disclosure.

FIG. 3A is a Y-Z cross-sectional view of the semiconductor device, in accordance with some alternative embodiments of the present disclosure.

FIG. 3B is an X-Z cross-sectional view of the semiconductor device, in accordance with some alternative embodiments of the present disclosure.

FIG. 4A is a Y-Z cross-sectional view of the semiconductor device, in accordance with some alternative embodiments of the present disclosure.

FIG. 4B is an X-Z cross-sectional view of the semiconductor device, in accordance with some alternative embodiments of the present disclosure.

FIG. 5A is a Y-Z cross-sectional view of the semiconductor device, in accordance with some alternative embodiments of the present disclosure.

FIG. 5B is an X-Z cross-sectional view of the semiconductor device, in accordance with some alternative embodiments of the present disclosure.

FIG. 6A is a Y-Z cross-sectional view of the semiconductor device, in accordance with some alternative embodiments of the present disclosure.

FIG. 6B is an X-Z cross-sectional view of the semiconductor device, in accordance with some alternative embodiments of the present disclosure.

FIG. 7A is a Y-Z cross-sectional view of the semiconductor device, in accordance with some alternative embodiments of the present disclosure.

FIG. 7B is an X-Z cross-sectional view of the semiconductor device, in accordance with some alternative embodiments of the present disclosure.

FIG. 8A is a Y-Z cross-sectional view of the semiconductor device, in accordance with some alternative embodiments of the present disclosure.

FIG. 8B is an X-Z cross-sectional view of the semiconductor device, in accordance with some alternative embodiments of the present disclosure.

FIG. 9 is a perspective view of a workpiece at a fabrication stage, in accordance with some embodiments of the present disclosure.

FIGS. 10, 11A, 12A, 13A, 14A, 15A, 16A, 17A, 18A, 19A, 22A, 23A, 24A, 25A, 26A, 27A, 28A, 29A, 30A, 31A, and 32A are Y-Z cross-sectional views of the workpiece at various fabrication stages along line C-C′ of FIG. 9, in accordance with some embodiments of the present disclosure.

FIGS. 12B, 13B, 14B, 15B, 16B, 17B, 18B, 19B, 20A, 21A, 22B, 23B, 24B, 25B, 26B, 27B, 28B, 29B, 30B, 31B, and 32B are X-Z cross-sectional views of the workpiece at various fabrication stages along line D-D′ of FIG. 9, in accordance with some embodiments of the present disclosure.

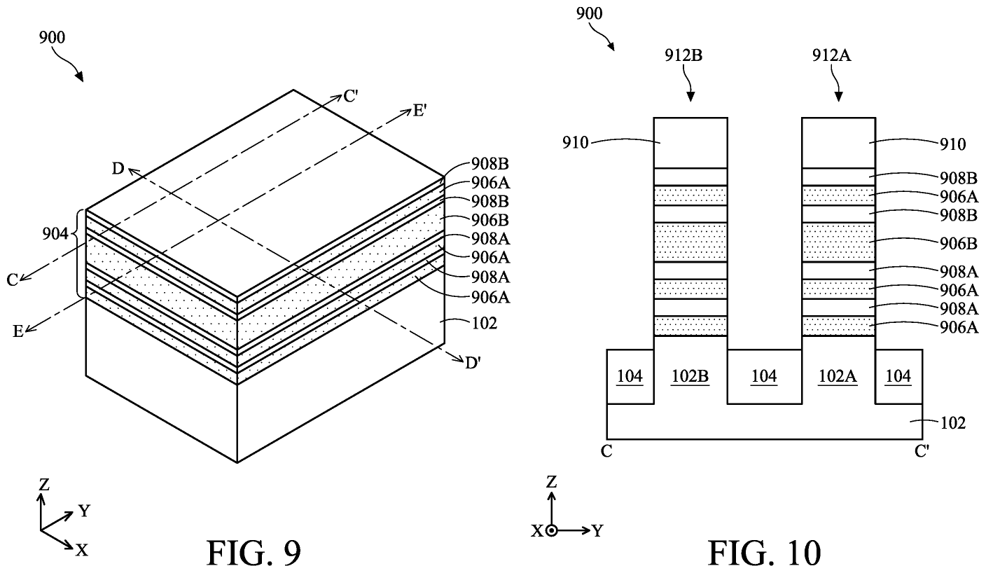

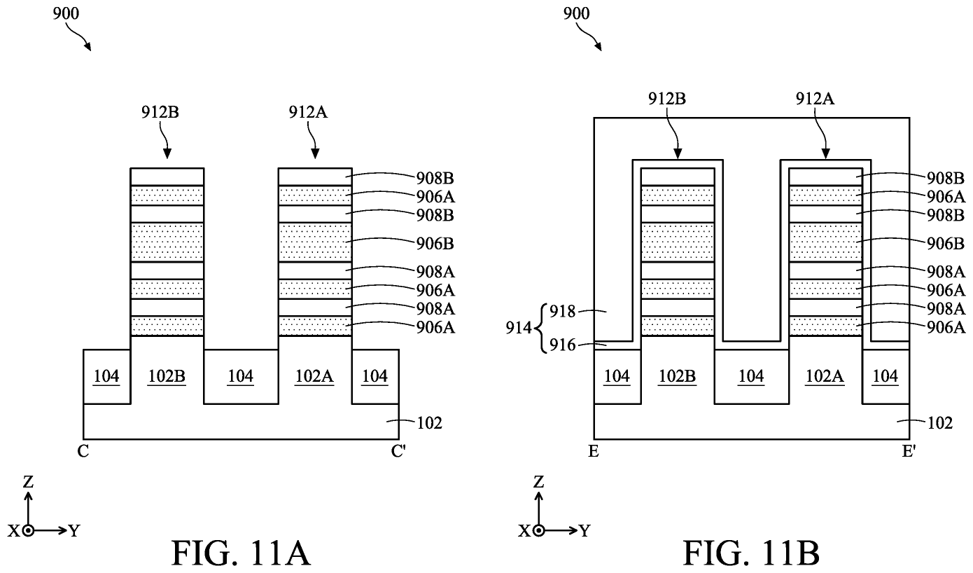

FIGS. 11B, 20B, and 21B are Y-Z cross-sectional views of the workpiece at various fabrication stages along line E-E′ of FIG. 9, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures. Generally, a CFET may include an n-type FET (NFET) and a p-type FET (PFET) disposed vertically with a plurality of vertically stacked sheets (e.g., nanosheets), wires (e.g., nanowires), or rods (e.g., nanorods) in a channel region of the CFET, thereby allowing better gate control, lowered leakage current, and improved scaling capability for various IC applications.

The GAA structures may be patterned by any suitable method. For example, the GAA structures may be patterned using one or more photolithography processes, including double-patterning or multi-patterning processes. Generally speaking, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and is patterned using a photolithography process. Spacers are formed alongside the patterned sacrificial layer using a self-aligned process. The sacrificial layer is then removed, and the remaining spacers may then be used to pattern the GAA structure.

In the existing CFET device, source/drain (S/D) features of NFET and PFET may sometimes be connected together by a frontside S/D local-interconnection (LI) contact, and the frontside S/D LI contact may be connected to signals. For example, in a static random access memory (SRAM) device, a frontside S/D LI contact may connect drains of a pull-down (PD) transistor and a pull-up (PD) transistor that form an inverter, and then connect to a pass-gate (PG) transistor and another inverter of the SRAM device (i.e., signals). However, it results in signal routing being restricted to the frontside of the device. In advanced technology node, since the geometric size is decreased, the routing restricted to the frontside of the device may not provide interconnection that is good enough. Therefore, a novel structure and fabricating method are needed to provide flexibility for the signal routing.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that have a backside S/D contact that corresponds to the frontside S/D LI contact and is formed on the backside of the device. In this way, the signals could be transmitted between the frontside S/D LI contact and the backside S/D contact. As a result, the signal routing can be arranged on the frontside of the device (e.g., by connecting to the frontside S/D LI contact), arranged on the backside of the device (e.g., by connecting to the backside S/D contact), or distributed on both the frontside and the backside (e.g., by connecting to both the frontside S/D LI contact and the backside S/D contact). Therefore, the flexibility for the signal routing is provided. Similarly, alternative embodiments discussed herein include methods and structures that have a frontside S/D contact and a corresponding backside S/D LI contact that connects S/D features of NFET and PFET together. It also provides flexibility for the signal routing. On the other hand, the embodiments provided by the present disclosure are not limited to the signal routing, they can further be applied to any device having a S/D LI contact to provide the flexibility for the routing of the interconnection structure.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

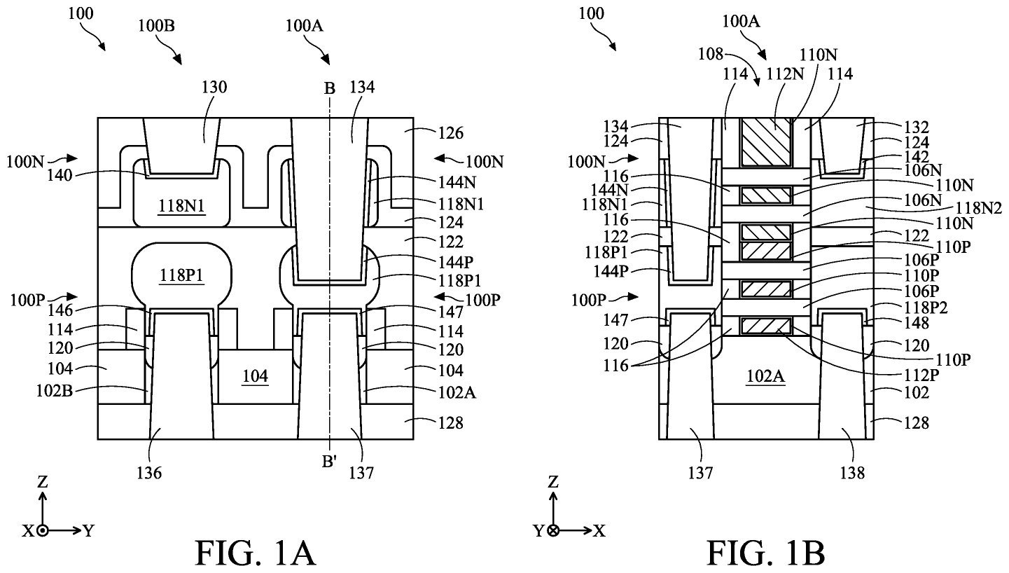

FIG. 1A is a Y-Z cross-sectional view of a semiconductor device 100, in accordance with some embodiments of the present disclosure. FIG. 1B is an X-Z cross-sectional view of the semiconductor device 100 along line B-B′ of FIG. 1A, in accordance with some embodiments of the present disclosure.

Referring to FIGS. 1A and 1B, the semiconductor device 100 includes two complementary field effect transistors (CFETs) 100A and 100B that are arranged in the Y-direction, in accordance with some embodiments. The CFETs 100A and 100B have similar structure and features. Furthermore, each of the CFETs 100A and 100B has a p-type field effect transistor (PFET) 100P and an n-type field effect transistors (NFETs) 100N. In each of the CFETs 100A and 100B, the NFET 100N is disposed over (or vertically overlaps) the PFET 100P in the Z-direction, as shown in FIGS. 1A and 1B. In other embodiments, the PFET may be disposed over the NFET in the Z-direction.

The semiconductor device 100 further includes a substrate 102, as shown in FIGS. 1A and 1B. The substrate 102 includes a base portion 102A for the CFET 100A and a base portion 102B for the CFET 100B, which are protruded from the substrate 102 under the nanostructures 106P and 106N. Subsequent features for the CFETs 100A and 100B are formed over the base portions 102A and 102B of the substrate 102, as described in further detail below. In some embodiments, after the resultant NFETs 100N and PFETs 100P of the CFETs 100A and 100B are formed, the substrate 102 may be thinned (or partially removed) by a suitable process (e.g., a chemical mechanical polishing (CMP) process) for forming backside interconnection.

In some embodiments, the semiconductor device 100 further includes isolation structures 104 in and/or over the substrate 102. The isolation structures 104 are formed between the base portions 102A and 102B of the substrate 102. In some embodiments, top surfaces of the isolation structures 104 are lower than top surfaces of the substrate 102 (more specifically, top surfaces of the base portions 102A and 102B).

Still referring to FIGS. 1A and 1B, the semiconductor device 100 further includes two groups of nanostructures, such as a group of nanostructures 106P and a group of nanostructures 106N (which may be collectively referred to as the nanostructures 106), in accordance with some embodiments. In some embodiments, the nanostructures 106 may also be referred to as channels, channel layers, nanosheets, or nanowires. In some embodiments, the nanostructures 106N are disposed over (or vertically overlap) the nanostructures 106P in the Z-direction. The nanostructures 106P are used for the PFETs in the CFETs and the nanostructures 106N are used for the NFETs in the CFETs. Furthermore, the nanostructures 106 are suspended over the base portions 102A and 102B of the substrate 102.

In some embodiments, the nanostructures 106 are extended in the X-direction and vertically stacked (or arranged) in the Z-direction. Specifically, the nanostructures 106 are spaced apart from each other in the Z-direction. In some embodiments, the distance between the topmost nanostructure 106P and the bottommost nanostructure 106N is greater than the distance between two nanostructures 106P or the distance between two nanostructures 106N, as shown in FIG. 1B.

In the embodiment depicted in FIG. 1B, two nanostructures 106 are vertically stacked (or vertically arranged) from each other in the Z-direction for one transistor. For example, in CFET 100A, the NFET 100N has two nanostructures 106N vertically stacked from each other in the Z-direction, and the PFET 100P has two nanostructures 106P vertically stacked from each other in the Z-direction. However, there may be another appropriate number of nanostructures in one transistor. For example, there may be 1, 2, 3, 4, or more than 4 nanostructures 106 in one transistor.

In some embodiments, the semiconductor device 100 further includes a gate structure 108 wrapped around the nanostructures 106. Specifically, the gate structure 108 wraps around the nanostructures 106P in the PFETs 100P and the nanostructures 106N in the NFETs 100N. The CFETs 100A and 100B share the gate structure 108. More specifically, the gate structure 108 extend in the Y-direction to wrap around the nanostructures 106 in the CFET 100A and the CFET 100B. In some embodiments, the gate structure 108 has a length in the X-direction (i.e., gate length) that is in a range from about 6 nm (nanometer) to about 20 nm.

The gate structure 108 has a gate dielectric layer 110P, a gate electrode layer 112P, a gate dielectric layer 110N, and a gate electrode layer 112N (the gate dielectric layers 110P and 110N may be collectively referred to as the gate dielectric layers 110, and the gate electrode layers 112P and 112N may be collectively referred to as the gate electrode layers 112). As shown in FIG. 1B, the gate dielectric layer 110P wraps around each of the nanostructures 106P in the PFETs 100P, and the gate dielectric layer 110N wraps around each of the nanostructures 106N in the NFETs 100N. The gate electrode layer 112P wraps around the gate dielectric layer 110P and each of the nanostructures 106P in the PFETs 100P, and the gate electrode layer 112N wraps around the gate dielectric layer 110N and each of the nanostructures 106N in the NFETs 100N.

In some embodiments, the gate dielectric layer 110P is also formed on top surfaces of the isolation structures 104 and top surfaces and sidewalls of the substrate 102 (more specifically, the top surfaces and sidewalls of the base portions 102A and 102B) (not shown). The gate dielectric layer 110N is also formed on the top surface of the gate electrode layer 112P, as shown in FIG. 1B. In some embodiments, the gate dielectric layer 110P is further formed on sidewalls of inner spacers 116 (discussed below), and the gate dielectric layer 110N is further formed on sidewalls of the gate spacer 114 (discussed below) and the inner spacers 116, as shown in FIG. 1B. In some embodiments, the gate dielectric layer 110P is in contact with the gate dielectric layer 110N, as shown in FIG. 1B.

In some embodiments, the gate structure 108 further includes an interfacial layer (not shown, such as having silicon dioxide, silicon oxynitride, or other suitable materials) between the gate dielectric layers 110 and the nanostructures 106. As discussed above, the gate electrode layers 112P and 112N are formed to wrap around the gate dielectric layers 110P and 110N and the nanostructures 106, as shown in FIG. 1B.

In some embodiments, the semiconductor device 100 further includes gate spacers 114 on opposite sides of the gate structure 108. More specifically, the gate spacers 114 are on sidewalls of the gate structures 108 and over the nanostructures 106, as shown in FIG. 1B. Furthermore, the gate spacers 114 extend lengthwise in the Y-direction (e.g., parallel to the gate structure 108), and are on opposite sides (or on opposite sidewalls) of the gate structure 108 in the X-direction. The gate spacers 114 are over the nanostructures 106 and on top sidewalls of the gate structures 108, and thus are also referred to as gate top spacers or top spacers.

In some embodiments, the semiconductor device 100 further includes inner spacers 116 on opposite sides of the gate structure 108. More specifically, the inner spacers 116 are on the sidewalls of the gate structure 108, and below the gate spacers 114 and the topmost nanostructure 106N. As shown in FIG. 1B, the inner spacers 116 are also vertically between adjacent nanostructures 106N, vertically between adjacent nanostructures 106N and 106P, vertically between adjacent nanostructures 106P, and vertically between the bottommost nanostructures 106P and the substrate 102, in accordance with some embodiments. In some embodiments, a thickness of the inner spacers 116 vertically between adjacent nanostructures 106N and 106P in the Z-direction is greater than thicknesses of other inner spacers 116, as shown in FIG. 1B. Furthermore, the inner spacers 116 are laterally between the source/drain features 118N/118P (described below) and the gate structure 108 in the X-direction.

Still referring to FIGS. 1A and 1B, each of the CFETs 100A and 100B includes source/drain features 118P1, 118P2 (may be collectively referred to as the source/drain features 118P) and source/drain features 118N1, 118N2 (may be collectively referred to as the source/drain features 118N) over the substrate 102, in accordance with some embodiments. More specifically, the source/drain features 118P1 and 118P2 are disposed over the substrate 102, and the source/drain features 118N1 and 118N2 are disposed over (or vertically overlap) the source/drain features 118P1 and 118P2, respectively. In some embodiments, the source/drain features 118N are vertically separated from the source/drain features 118P in the Z-direction, as shown in FIGS. 1A and 1B. In some embodiments, the source/drain features 118N are disposed on opposite sides of the gate structure 108 in the X-direction to form the NFETs 100N, as shown in FIG. 1B. Similarly, the source/drain features 118P are disposed on opposite sides of the gate structure 108P in the X-direction to form the PFETs 100P, as shown in FIG. 1B.

The nanostructures 106 extend in the X-direction to connect one source/drain feature 118P/118N to the other source/drain feature 118P/118N, in accordance with some embodiments. More specifically, the source/drain features 118P1 and 118P2 are disposed on opposite sides of the nanostructures 106P and the source/drain features 118N1 and 118N2 are disposed on opposite sides of the nanostructures 106N in the X-direction. Therefore, the source/drain features 118P are attached and electrically connected to the nanostructures 106P in the X-direction, and the source/drain features 118N are attached and electrically connected to the nanostructures 106N in the X-direction. The source/drain features 118P/118N may also be referred to as source/drain, or source/drain regions. In some embodiments, source/drain feature(s) may refer to a source or a drain, individually or collectively dependent upon the context.

Still referring to FIGS. 1A and 1B, the semiconductor device 100 further includes bottom isolation layers 120 under the source/drain features 118N and 118P and over the substrate 102 in the Z-direction, in accordance with some embodiments. In some embodiments, the bottom isolation layers 120 are vertically between and in contact with the source/drain features 118P and the substrate 102 in the Z-direction. In some embodiments, the top surfaces of the bottom isolation layers 120 are higher than the bottommost surface of the gate structure 108, as shown in FIG. 1B. In some aspects, the top surfaces of the bottom isolation layers 120 are higher than the topmost surfaces of the substrate 102 (i.e., the top surfaces of the base portions 102A and 102B), so as to ensure that the bottom isolation layers 120 separate the source/drain features 118P from the substrate 102. The bottom isolation layers 120 may be a single layer structure or a multi-layer structure.

Still referring to FIGS. 1A and 1B, the semiconductor device 100 further includes an interlayer dielectric (ILD) layer 122 over the substrate 102, the isolation structures 104, and the source/drain features 118P, in accordance with some embodiments. In some embodiments, the ILD layer 122 is also between and fill the spaces between the source/drain features 118P in the Y-direction, as shown in FIG. 1A. In these embodiments, the source/drain features 118P are surrounded by the ILD layer 122 in the Y-direction. In some embodiments, the ILD layer 122 is vertically between and in contact with the source/drain features 118P and the source/drain features 118N in the Z-direction. For example, the ILD layer 122 is vertically between the source/drain feature 118P1 and 118N1, and is vertically between the source/drain feature 118P2 and 118N2. Thus, the source/drain features 118P are separated and electrically isolated from the source/drain features 118N by the ILD layer 122.

Still referring to FIGS. 1A and 1B, the semiconductor device 100 further includes contact etch stop layers (CESLs) 124 and an ILD layer 126 over the CESLs 124, in accordance with some embodiments. The CESLs 124 are over the source/drain features 118N and the ILD layer 122, and the ILD layer 126 is formed to fill the space between the source/drain features 118N. Specifically, the CESLs 124 are conformally formed on the sidewalls of the gate spacers 114. In some embodiments, the CESLs 124 are also conformally formed on the top surfaces and the sidewalls of the source/drain features 118N, as shown in FIG. 1A. The ILD layer 126 is formed over and between the CESLs 124 to fill the space in the CESLs 124 and between the gate spacers 114.

Still referring to FIGS. 1A and 1B, the semiconductor device 100 further includes an ILD layer 128 under the substrate 102, in accordance with some embodiments.

Still referring to FIGS. 1A and 1B, the semiconductor device 100 further includes source/drain contacts 130 and 132, in accordance with some embodiments. In some embodiments, the source/drain contacts 130 and 132 pass through the ILD layer 126, the CESLs 124, and portions of the source/drain features 118N, so as to be in contact with and electrically connected to the source/drain features 118N. In other words, the source/drain contacts 130 and 132 extend through the ILD layer 126 and the CESLs 124, and partially extend into the source/drain features 118N. In some embodiments, the source/drain contact 130 is in contact with and electrically connected to the source/drain feature 118N1 of the CFET 100B, as shown in FIG. 1A. In some embodiments, the source/drain contact 132 is in contact with and electrically connected to the source/drain feature 118N2 of the CFET 100A, as shown in FIG. 1B.

Still referring to FIGS. 1A and 1B, the semiconductor device 100 further includes silicide layers 140 and 142 that are between the source/drain contacts 130 and 132 and the source/drain features 118N, respectively, in accordance with some embodiments. In some embodiments, the silicide layer 140 is formed on the interface between the source/drain contact 130 and the source/drain feature 118N1 of the CFET 100B, as shown in FIG. 1A. That is, the silicide layer 140 is formed on sidewalls and the bottom surface of a portion of the source/drain contact 130 inside the source/drain feature 118N1 of the CFET 100B. In some embodiments, the silicide layer 142 is formed on the interface between the source/drain contact 132 and the source/drain feature 118N2 of the CFET 100A, as shown in FIG. 1B. That is, the silicide layer 142 is formed on sidewalls and the bottom surface of a portion of the source/drain contact 132 inside the source/drain feature 118N2 of the CFET 100A.

Still referring to FIGS. 1A and 1B, the semiconductor device 100 further includes a source/drain contact 134, in accordance with some embodiments. In some embodiments, the source/drain contact 134 passes through the ILD layer 126, the CESLs 124, the source/drain feature 118N, the ILD layer 122, and portions of the source/drain feature 118P, so as to be in contact with and electrically connected to both of the source/drain features 118N and 118P. In other words, the source/drain contact 134 extends through the ILD layer 126, the CESLs 124, the source/drain feature 118N, and the ILD layer 122, and partially extend into the source/drain feature 118P. In some embodiments, the source/drain contact 134 is in contact with and electrically connected to the source/drain feature 118N1 and the source/drain feature 118P1 of the CFET 100A, as shown in FIGS. 1A and 1B. That is, the source/drain contact 134 electrically connects the source/drain feature 118N1 and the source/drain feature 118P1 of the CFET 100A together.

In some embodiments, since the source/drain contacts 130, 132, and 134 are formed on the frontside of the semiconductor device 100, the source/drain contacts 130, 132, and 134 may be referred to as frontside source/drain contacts. Furthermore, since the source/drain contact 134 connects the source/drain features 118N and 118P of NFET 100N and PFET 100P together, the source/drain contact 134 may be referred to as the frontside S/D local-interconnection (LI) contact.

Still referring to FIGS. 1A and 1B, the semiconductor device 100 further includes silicide layers 144N and 144P that are between the source/drain contact 134 and the source/drain features 118N and 118P, respectively, in accordance with some embodiments. In some embodiments, the silicide layer 144N is formed on the interface between the source/drain contact 134 and the source/drain feature 118N1 of the CFET 100A, as shown in FIGS. 1A and 1B. That is, the silicide layer 144N is formed on sidewalls of a portion of the source/drain contact 134 inside the source/drain feature 118N1 of the CFET 100A. In some embodiments, the silicide layer 144P is formed on the interface between the source/drain contact 134 and the source/drain feature 118P1 of the CFET 100A, as shown in FIGS. 1A and 1B. That is, the silicide layer 144P is formed on sidewalls and the bottom surface of a portion of the source/drain contact 134 inside the source/drain feature 118P1 of the CFET 100A. In some embodiments, the material of the silicide layer 144N is different from the material of the silicide layer 144P.

Still referring to FIGS. 1A and 1B, the semiconductor device 100 further includes source/drain contacts 136, 137, and 138, in accordance with some embodiments. In some embodiments, the source/drain contacts 136, 137, and 138 pass through the ILD layer 128, the substrate 102, the bottom isolation layers 120, and portions of the source/drain features 118P, so as to be in contact with and electrically connected to the source/drain features 118P. In other words, the source/drain contacts 136, 137, and 138 extend through the ILD layer 128, the substrate 102, and the bottom isolation layers 120, and partially extend into the source/drain features 118P. In some embodiments, since the source/drain contacts 136, 137, and 138 are formed on backside of the semiconductor device 100, the source/drain contacts 136, 137, and 138 may be referred to as backside source/drain contacts or bottom source/drain contacts.

In some embodiments, the source/drain contact 136 is in contact with and electrically connected to the source/drain feature 118P1 of the CFET 100B, as shown in FIG. 1A. In some embodiments, the source/drain contact 137 is in contact with and electrically connected to the source/drain feature 118P1 of the CFET 100A, as shown in FIGS. 1A and 1B. In some embodiments, the source/drain contact 138 is in contact with and electrically connected to the source/drain feature 118P2 of the CFET 100A, as shown in FIG. 1B.

Still referring to FIGS. 1A and 1B, the semiconductor device 100 further includes silicide layers 146, 147, and 148 that are between the source/drain contacts 136, 137, and 138 and the source/drain features 118P, respectively, in accordance with some embodiments. In some embodiments, the silicide layer 146 is formed on the interface between the source/drain contact 136 and the source/drain feature 118P1 of the CFET 100B, as shown in FIG. 1A. That is, the silicide layer 146 is formed on sidewalls and the top surface of a portion of the source/drain contact 136 inside the source/drain feature 118P1 of the CFET 100B.

In some embodiments, the silicide layer 147 is formed on the interface between the source/drain contact 137 and the source/drain feature 118P1 of the CFET 100A, as shown in FIGS. 1A and 1B. That is, the silicide layer 147 is formed on sidewalls and the top surface of a portion of the source/drain contact 137 inside the source/drain feature 118P1 of the CFET 100A. In some embodiments, the material of the silicide layer 147 is different from the materials of the silicide layers 144N and 144P. In some embodiments, the silicide layer 148 is formed on the interface between the source/drain contact 138 and the source/drain feature 118P2 of the CFET 100A, as shown in FIG. 1B. That is, the silicide layer 148 is formed on sidewalls and the top surface of a portion of the source/drain contact 138 inside the source/drain feature 118P2 of the CFET 100A.

In some embodiments, the source/drain contact 134 is electrically connected to the source/drain contact 137 through the silicide layer 144P, the source/drain feature 118P1 of the CFET 100A, and the silicide layer 147. In these embodiments, a portion of the source/drain feature 118P1 of the CFET 100A is between the source/drain contact 134 (and the silicide layers 144P formed thereon) and the source/drain contact 137 (and the silicide layers 147 formed thereon), as shown in FIGS. 1A and 1B. In other words, a horizontal portion of the silicide layer 144P formed on the bottom surface of the source/drain contact 134 is separated from a horizontal portion of the silicide layer 147 formed on the top surface of the source/drain contact 137 by a portion of the source/drain feature 118P1 of the CFET 100A.

In some embodiments, the source/drain contact 134 and/or the source/drain contact 137 are connected to signals. Since the source/drain contact 134 is electrically connected to the source/drain contact 137, the signals could be transmitted between the source/drain contacts 134 and 137. Therefore, the source/drain features 118N1 and 118P1 of the CFET 100A connected together by the source/drain contact 134 can be connected to signals through the source/drain contact 134, through the source/drain contact 137, or through both of the source/drain contacts 134 and 137. In this way, the signal routing can be arranged on the frontside of the semiconductor device 100 (by connecting to the source/drain contact 134), arranged on the backside of the semiconductor device 100 (by connecting to the source/drain contact 137), or distributed on the frontside and backside of the semiconductor device 100 (by connecting to both of the source/drain contacts 134 and 137). Accordingly, the flexibility for the signal routing can be improved.

In some embodiments where the semiconductor device 100 is applied to a static random access memory (SRAM) device, the NFET 100N and the PFET 100P of the CFET 100A may act as a PD transistor and a PU transistor and constitute an inverter. Furthermore, the source/drain features 118N1 and 118P1 of the CFET 100A may act as drains of the PD transistor and the PU transistor, and are connected together by the source/drain contact 134. In these embodiments, the signals connected to the source/drain features 118N1 and 118P1 of the CFET 100A may come from another inverter and a PG transistor of the SRAM device.

In some embodiments, an interconnection structure (not shown) of the signal routing is arranged on the frontside of the semiconductor device 100, and connects the source/drain contact 134 to the PG transistor and another inverter. In these embodiments, the signals coming from the PG transistor and another inverter are transmitted to the source/drain features 118N1 and 118P1 of the CFET 100A through the source/drain contact 134. In other embodiments, an interconnection structure (not shown) of the signal routing is arranged on the backside of the semiconductor device 100, and connects the source/drain contact 137 to the PG transistor and another inverter. In these embodiments, the signals coming from the PG transistor and another inverter are transmitted to the source/drain features 118N1 and 118P1 of the CFET 100A through the source/drain contacts 137 and 134.

In certain embodiments, an interconnection structure (not shown) of the signal routing is distributed on both of the frontside and backside of the semiconductor device 100, and connects the source/drain contacts 134 and 137 to the PG transistor and another inverter. For example, the interconnection structure of the signal routing may connect the source/drain contacts 134 and 137 to the PG transistor and another inverter, respectively. Alternatively, the interconnection structure of the signal routing may connect the source/drain contacts 134 and 137 to another inverter and the PG transistor, respectively. For example, the interconnection structure of the signal routing may first connect the source/drain contacts 134 and 137 together, and then connect them to both of the PG transistor and another inverter. In these embodiments, the signals coming from the PG transistor and another inverter are transmitted to the source/drain features 118N1 and 118P1 of the CFET 100A through the source/drain contacts 137 and 134.

In some embodiments, the source/drain contacts 130, 132, 136, and 138 are connected to powers. For example, when the semiconductor device 100 is applied to a SRAM device, the source/drain contacts 130, 132, 136, and 138 may connect to a positive power supply VDD or a negative power supply (or ground) VSS.

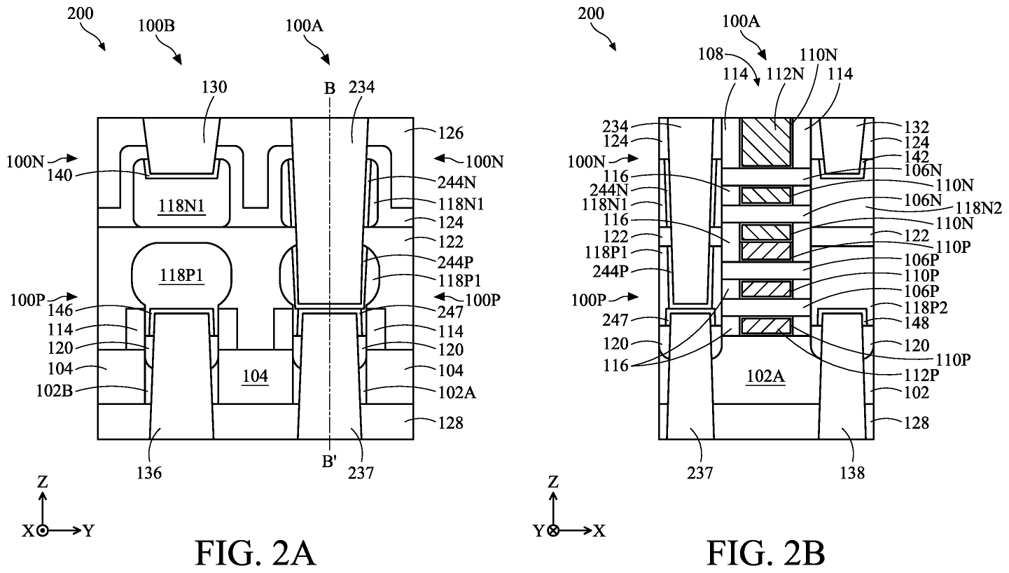

FIG. 2A is a Y-Z cross-sectional view of a semiconductor device 200, in accordance with alternative embodiments of the present disclosure. FIG. 2B is an X-Z cross-sectional view of the semiconductor device 200 along line B-B′ of FIG. 2A, in accordance with alternative embodiments of the present disclosure. The semiconductor device 200 shown in FIGS. 2A and 2B may be similar to the semiconductor device 100 shown in FIGS. 1A and 1B, except the source/drain contacts 134, 137 and the silicide layers 144N, 144P, 147 shown in FIGS. 1A and 1B are replaced by source/drain contacts 234, 237 and silicide layers 244N, 244P, 247 shown in FIGS. 2A and 2B.

Referring to FIGS. 2A and 2B, similar to the source/drain contact 134 shown in FIGS. 1A and 1B, the source/drain contact 234 extends through the ILD layer 126, the CESLs 124, the source/drain feature 118N, and the ILD layer 122, and partially extend into the source/drain feature 118P, so as to be in contact with and electrically connected to both of the source/drain features 118N and 118P, in accordance with some embodiments. In some embodiments, the source/drain contact 234 is in contact with the source/drain features 118N1 and 118P1 of the CFET 100A, and electrically connects them together, as shown in FIGS. 2A and 2B. Similar to the source/drain contact 134, the source/drain contact 234 may be referred to as the frontside S/D LI contact.

In some embodiments, similar to the silicide layer 144N shown in FIGS. 1A and 1B, the silicide layer 244N is formed on the interface between the source/drain contact 234 and the source/drain feature 118N1 of the CFET 100A, as shown in FIGS. 2A and 2B. In some embodiments, similar to the silicide layer 144P shown in FIGS. 1A and 1B, the silicide layer 244P is formed on the interface between the source/drain contact 234 and the source/drain feature 118P1 of the CFET 100A, as shown in FIGS. 2A and 2B. That is, the silicide layer 244P is formed on sidewalls and the bottom surface of a portion of the source/drain contact 234 inside the source/drain feature 118P1 of the CFET 100A. In some embodiments, the material of the silicide layer 244N is different from the material of the silicide layer 244P.

Still referring to FIGS. 2A and 2B, similar to the source/drain contact 137 shown in FIGS. 1A and 1B, the source/drain contact 237 extends through the ILD layer 128, the substrate 102, and the bottom isolation layer 120, and partially extend into the source/drain feature 118P, so as to be in contact with and electrically connected to the source/drain feature 118P, in accordance with some embodiments. In some embodiments, the source/drain contact 237 is in contact with and electrically connected to the source/drain feature 118P1 of the CFET 100A, as shown in FIGS. 2A and 2B. Similar to the source/drain contact 137, the source/drain contact 237 may be referred to as backside source/drain contact or bottom source/drain contact.

In some embodiments, similar to the silicide layer 147 shown in FIGS. 1A and 1B, the silicide layer 247 is formed on the interface between the source/drain contact 237 and the source/drain feature 118P1 of the CFET 100A, as shown in FIGS. 2A and 2B. That is, the silicide layer 247 is formed on sidewalls and the top surface of a portion of the source/drain contact 237 inside the source/drain feature 118P1 of the CFET 100A. In some embodiments, the material of the silicide layer 247 is different from the materials of the silicide layers 244N and 244P.

In some embodiments, the source/drain contact 234 is electrically connected to the source/drain contact 237 through the silicide layer 244P and the silicide layer 247. In these embodiments, the silicide layer 244P is in direct contact with the silicide layer 247 in the source/drain feature 118P1 of the CFET 100A, as shown in FIGS. 2A and 2B. That is, a horizontal portion of the silicide layer 244P formed on the bottom surface of the source/drain contact 234 is in direct contact with a horizontal portion of the silicide layer 247 formed on the top surface of the source/drain contact 237 in the source/drain feature 118P1 of the CFET 100A.

In some embodiments, the source/drain contact 234 and/or the source/drain contact 237 are connected to signals. Similar to the source/drain contacts 134 and 137 described above, the arrangement of the source/drain contacts 234 and 237 can allow the signal routing to be arranged on the frontside, the backside, or both of the frontside and backside of the semiconductor device 200. As a result, the flexibility for the signal routing can be improved. In some embodiments where the semiconductor device 200 is applied to a SRAM device, the source/drain contacts 234 and 237 may function as the source/drain contacts 134 and 137 in the embodiments where the semiconductor device 100 is applied to the SRAM device.

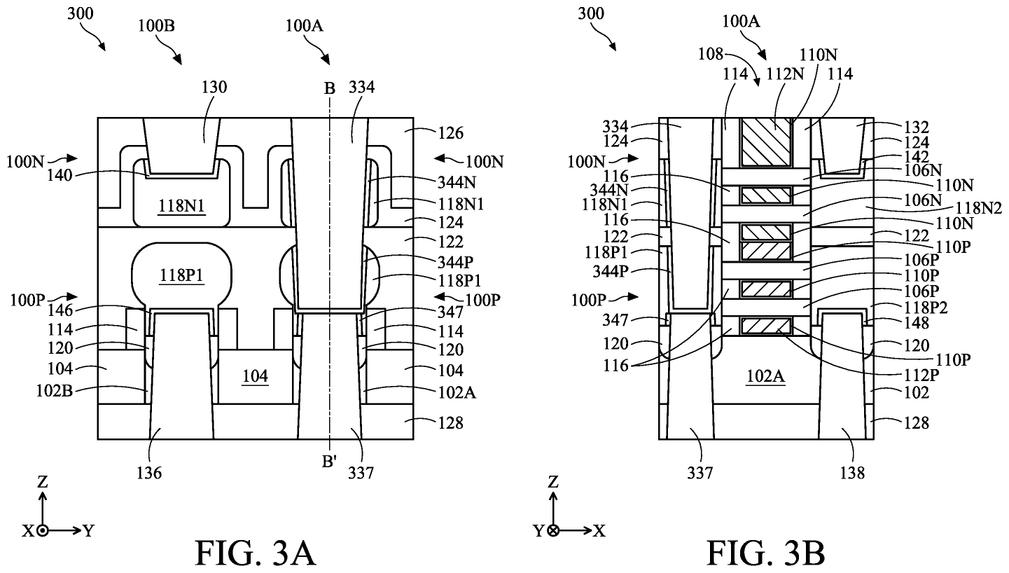

FIG. 3A is a Y-Z cross-sectional view of a semiconductor device 300, in accordance with alternative embodiments of the present disclosure. FIG. 3B is an X-Z cross-sectional view of the semiconductor device 300 along line B-B′ of FIG. 3A, in accordance with alternative embodiments of the present disclosure. The semiconductor device 300 shown in FIGS. 3A and 3B may be similar to the semiconductor device 100 shown in FIGS. 1A and 1B, except the source/drain contacts 134, 137 and the silicide layers 144N, 144P, 147 shown in FIGS. 1A and 1B are replaced by source/drain contacts 334, 337 and silicide layers 344N, 344P, 347 shown in FIGS. 3A and 3B.

Referring to FIGS. 3A and 3B, similar to the source/drain contact 134 shown in FIGS. 1A and 1B, the source/drain contact 334 extends through the ILD layer 126, the CESLs 124, the source/drain feature 118N, and the ILD layer 122, and partially extend into the source/drain feature 118P, so as to be in contact with and electrically connected to both of the source/drain features 118N and 118P, in accordance with some embodiments. In some embodiments, the source/drain contact 334 is in contact with the source/drain features 118N1 and 118P1 of the CFET 100A, and electrically connects them together, as shown in FIGS. 3A and 3B. Similar to the source/drain contact 134, the source/drain contact 334 may be referred to as the frontside S/D LI contact.

In some embodiments, similar to the silicide layer 144N shown in FIGS. 1A and 1B, the silicide layer 344N is formed on the interface between the source/drain contact 334 and the source/drain feature 118N1 of the CFET 100A, as shown in FIGS. 3A and 3B. In some embodiments, similar to the silicide layer 144P shown in FIGS. 1A and 1B, the silicide layer 344P is formed on the interface between the source/drain contact 334 and the source/drain feature 118P1 of the CFET 100A, as shown in FIGS. 3A and 3B. That is, the silicide layer 344P is formed on sidewalls and the bottom surface of a portion of the source/drain contact 334 inside the source/drain feature 118P1 of the CFET 100A. In some embodiments, the material of the silicide layer 344N is different from the material of the silicide layer 344P.

Still referring to FIGS. 3A and 3B, similar to the source/drain contact 137 shown in FIGS. 1A and 1B, the source/drain contact 337 extends through the ILD layer 128, the substrate 102, and the bottom isolation layer 120, and partially extend into the source/drain feature 118P, so as to be in contact with and electrically connected to the source/drain feature 118P, in accordance with some embodiments. In some embodiments, the source/drain contact 337 is in contact with and electrically connected to the source/drain feature 118P1 of the CFET 100A, as shown in FIGS. 3A and 3B. Similar to the source/drain contact 137, the source/drain contact 337 may be referred to as backside source/drain contact or bottom source/drain contact.

In some embodiments, similar to the silicide layer 147 shown in FIGS. 1A and 1B, the silicide layer 347 is formed on the interface between the source/drain contact 337 and the source/drain feature 118P1 of the CFET 100A, as shown in FIGS. 3A and 3B. That is, the silicide layer 347 is formed on sidewalls of a portion of the source/drain contact 337 inside the source/drain feature 118P1 of the CFET 100A. In some embodiments, the material of the silicide layer 347 is different from the materials of the silicide layers 344N and 344P.

In some embodiments, the source/drain contact 334 is electrically connected to the source/drain contact 337 through the silicide layer 344P. In these embodiments, the silicide layer 344P is in direct contact with the source/drain contact 337 in the source/drain feature 118P1 of the CFET 100A, as shown in FIGS. 3A and 3B. That is, a horizontal portion of the silicide layer 344P formed on the bottom surface of the source/drain contact 334 is in direct contact with the top surface of the source/drain contact 337 in the source/drain feature 118P1 of the CFET 100A.

In some embodiments, the source/drain contact 334 and/or the source/drain contact 337 are connected to signals. Similar to the source/drain contacts 134 and 137 described above, the arrangement of the source/drain contacts 334 and 337 can allow the signal routing to be arranged on the frontside, the backside, or both of the frontside and backside of the semiconductor device 300. As a result, the flexibility for the signal routing can be improved. In some embodiments where the semiconductor device 300 is applied to a SRAM device, the source/drain contacts 334 and 337 may function as the source/drain contacts 134 and 137 in the embodiments where the semiconductor device 100 is applied to the SRAM device.

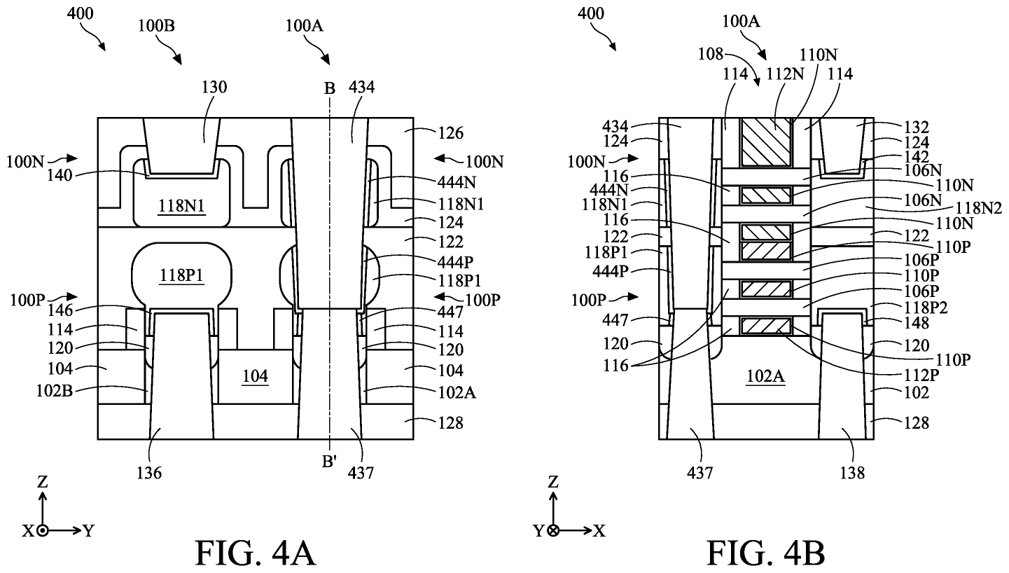

FIG. 4A is a Y-Z cross-sectional view of a semiconductor device 400, in accordance with alternative embodiments of the present disclosure. FIG. 4B is an X-Z cross-sectional view of the semiconductor device 400 along line B-B′ of FIG. 4A, in accordance with alternative embodiments of the present disclosure. The semiconductor device 400 shown in FIGS. 4A and 4B may be similar to the semiconductor device 100 shown in FIGS. 1A and 1B, except the source/drain contacts 134, 137 and the silicide layers 144N, 144P, 147 shown in FIGS. 1A and 1B are replaced by source/drain contacts 434, 437 and silicide layers 444N, 444P, 447 shown in FIGS. 4A and 4B.

Referring to FIGS. 4A and 4B, similar to the source/drain contact 134 shown in FIGS. 1A and 1B, the source/drain contact 434 extends through the ILD layer 126, the CESLs 124, the source/drain feature 118N, and the ILD layer 122, and partially extend into the source/drain feature 118P, so as to be in contact with and electrically connected to both of the source/drain features 118N and 118P, in accordance with some embodiments. In some embodiments, the source/drain contact 434 is in contact with the source/drain features 118N1 and 118P1 of the CFET 100A, and electrically connects them together, as shown in FIGS. 4A and 4B. Similar to the source/drain contact 134, the source/drain contact 434 may be referred to as the frontside S/D LI contact.

In some embodiments, similar to the silicide layer 144N shown in FIGS. 1A and 1B, the silicide layer 444N is formed on the interface between the source/drain contact 434 and the source/drain feature 118N1 of the CFET 100A, as shown in FIGS. 4A and 4B. In some embodiments, similar to the silicide layer 144P shown in FIGS. 1A and 1B, the silicide layer 444P is formed on the interface between the source/drain contact 434 and the source/drain feature 118P1 of the CFET 100A, as shown in FIGS. 4A and 4B. That is, the silicide layer 444P is formed on sidewalls of a portion of the source/drain contact 434 inside the source/drain feature 118P1 of the CFET 100A. In some embodiments, the material of the silicide layer 444N is different from the material of the silicide layer 444P.

Still referring to FIGS. 4A and 4B, similar to the source/drain contact 137 shown in FIGS. 1A and 1B, the source/drain contact 437 extends through the ILD layer 128, the substrate 102, and the bottom isolation layer 120, and partially extend into the source/drain feature 118P, so as to be in contact with and electrically connected to the source/drain feature 118P, in accordance with some embodiments. In some embodiments, the source/drain contact 437 is in contact with and electrically connected to the source/drain feature 118P1 of the CFET 100A, as shown in FIGS. 4A and 4B. Similar to the source/drain contact 137, the source/drain contact 437 may be referred to as backside source/drain contact or bottom source/drain contact.

In some embodiments, similar to the silicide layer 147 shown in FIGS. 1A and 1B, the silicide layer 447 is formed on the interface between the source/drain contact 437 and the source/drain feature 118P1 of the CFET 100A, as shown in FIGS. 4A and 4B. That is, the silicide layer 447 is formed on sidewalls of a portion of the source/drain contact 437 inside the source/drain feature 118P1 of the CFET 100A. In some embodiments, since the source/drain contact 437 is formed after the formation of the source/drain contact 434 and the silicide layer 444P, a portion of the silicide layer 444P is formed on sidewalls of the top portion of the source/drain contact 437, as shown in FIGS. 4A and 4B. In some embodiments, the material of the silicide layer 447 is different from the materials of the silicide layers 444N and 444P.

In some embodiments, the source/drain contact 434 is electrically connected to the source/drain contact 437 through the direct contact. In these embodiments, the source/drain contact 434 is in direct contact with the source/drain contact 437 in the source/drain feature 118P1 of the CFET 100A, as shown in FIGS. 4A and 4B. That is, the bottom surface of the source/drain contact 434 is in direct contact with the top surface of the source/drain contact 437 in the source/drain feature 118P1 of the CFET 100A.

In some embodiments, the source/drain contact 434 and/or the source/drain contact 437 are connected to signals. Similar to the source/drain contacts 134 and 137 described above, the arrangement of the source/drain contacts 434 and 437 can allow the signal routing to be arranged on the frontside, the backside, or both of the frontside and backside of the semiconductor device 400. As a result, the flexibility for the signal routing can be improved. In some embodiments where the semiconductor device 400 is applied to a SRAM device, the source/drain contacts 434 and 437 may function as the source/drain contacts 134 and 137 in the embodiments where the semiconductor device 100 is applied to the SRAM device.

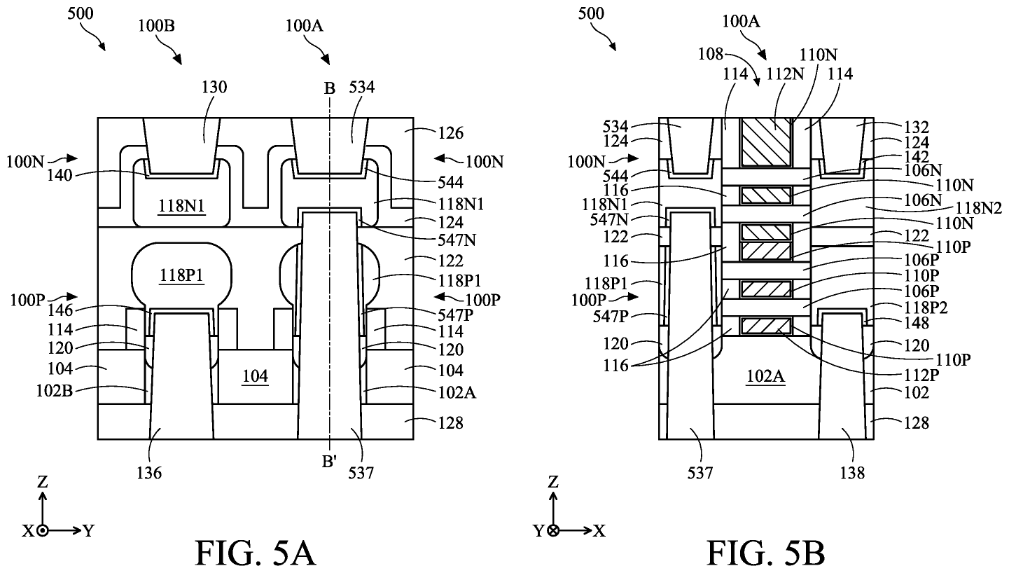

FIG. 5A is a Y-Z cross-sectional view of a semiconductor device 500, in accordance with alternative embodiments of the present disclosure. FIG. 5B is an X-Z cross-sectional view of the semiconductor device 500 along line B-B′ of FIG. 5A, in accordance with alternative embodiments of the present disclosure. The semiconductor device 500 shown in FIGS. 5A and 5B may be similar to the semiconductor device 100 shown in FIGS. 1A and 1B, except the source/drain contacts 134, 137 and the silicide layers 144N, 144P, 147 shown in FIGS. 1A and 1B are replaced by source/drain contacts 534, 537 and silicide layers 544, 547P, 547N shown in FIGS. 5A and 5B.

Referring to FIGS. 5A and 5B, the source/drain contact 534 extends through the ILD layer 126 and the CESLs 124, and partially extend into the source/drain feature 118N, so as to be in contact with and electrically connected to the source/drain feature 118N, in accordance with some embodiments. In some embodiments, the source/drain contact 534 is in contact with and electrically connected to the source/drain feature 118N1 of the CFET 100A, as shown in FIGS. 5A and 5B.

In some embodiments, the silicide layer 544 is formed on the interface between the source/drain contact 534 and the source/drain feature 118N1 of the CFET 100A, as shown in FIGS. 5A and 5B. That is, the silicide layer 544 is formed on sidewalls and bottom surface of a portion of the source/drain contact 534 inside the source/drain feature 118P1 of the CFET 100A.

Still referring to FIGS. 5A and 5B, the source/drain contact 537 passes through the ILD layer 128, the substrate 102, the bottom isolation layer 120, the source/drain feature 118P, the ILD layer 122, and portions of the source/drain feature 118N, so as to be in contact with and electrically connected to both of the source/drain features 118N and 118P. In other words, the source/drain contact 537 extends through the ILD layer 128, the substrate 102, the bottom isolation layer 120, the source/drain feature 118P, and the ILD layer 122, and partially extend into the source/drain feature 118N. In some embodiments, the source/drain contact 537 is in contact with and electrically connected to the source/drain features 118N1 and 118P1 of the CFET 100A, as shown in FIGS. 5A and 5B. That is, the source/drain contact 537 electrically connects the source/drain features 118N1 and 118P1 of the CFET 100A together. Similar to the source/drain contact 137, the source/drain contact 537 may be referred to as backside source/drain contact or bottom source/drain contact. Furthermore, since the source/drain contact 537 connects the source/drain features 118N and 118P of NFET 100N and PFET 100P together, the source/drain contact 537 may be referred to as the backside S/D LI contact.

In some embodiments, the silicide layers 547N and 547P are formed on the interfaces between the source/drain contact 537 and the source/drain features 118N and 118P, respectively, in accordance with some embodiments. In some embodiments, the silicide layer 547N is formed on the interface between the source/drain contact 537 and the source/drain feature 118N1 of the CFET 100A, as shown in FIGS. 5A and 5B. That is, the silicide layer 547N is formed on sidewalls and the top surface of a portion of the source/drain contact 537 inside the source/drain feature 118N1 of the CFET 100A. In some embodiments, the silicide layer 547P is formed on the interface between the source/drain contact 537 and the source/drain feature 118P1 of the CFET 100A, as shown in FIGS. 5A and 5B. That is, the silicide layer 547P is formed on sidewalls of a portion of the source/drain contact 537 inside the source/drain feature 118P1 of the CFET 100A. In some embodiments, the material of the silicide layer 547N is different from the material of the silicide layer 547P. In further embodiments, the material of the silicide layer 544 is different from the materials of the silicide layers 547N and 547P.

In some embodiments, the source/drain contact 534 is electrically connected to the source/drain contact 537 through the silicide layer 544, the source/drain feature 118N1 of the CFET 100A, and the silicide layer 547N. In these embodiments, a portion of the source/drain feature 118N1 of the CFET 100A is between the source/drain contact 534 (and the silicide layers 544 formed thereon) and the source/drain contact 537 (and the silicide layers 547N formed thereon), as shown in FIGS. 5A and 5B. In other words, a horizontal portion of the silicide layer 544 formed on the bottom surface of the source/drain contact 534 is separated from a horizontal portion of the silicide layer 547N formed on the top surface of the source/drain contact 537 by a portion of the source/drain feature 118N1 of the CFET 100A.

In some embodiments, the source/drain contact 534 and/or the source/drain contact 537 are connected to signals. Since the source/drain contact 534 is electrically connected to the source/drain contact 537, the signals could be transmitted between the source/drain contacts 534 and 537. Therefore, the source/drain features 118N1 and 118P1 of the CFET 100A connected together by the source/drain contact 537 can be connected to signals through the source/drain contact 534, through the source/drain contact 537, or through both of the source/drain contacts 534 and 537. In this way, the signal routing can be arranged on the frontside of the semiconductor device 500 (by connecting to the source/drain contact 534), arranged on the backside of the semiconductor device 500 (by connecting to the source/drain contact 537), or distributed on the frontside and backside of the semiconductor device 500 (by connecting to both of the source/drain contacts 534 and 537). Accordingly, the flexibility for the signal routing can be improved. In some embodiments where the semiconductor device 500 is applied to a SRAM device, the source/drain contacts 534 and 537 may function as the source/drain contacts 134 and 137 in the embodiments where the semiconductor device 100 is applied to the SRAM device.

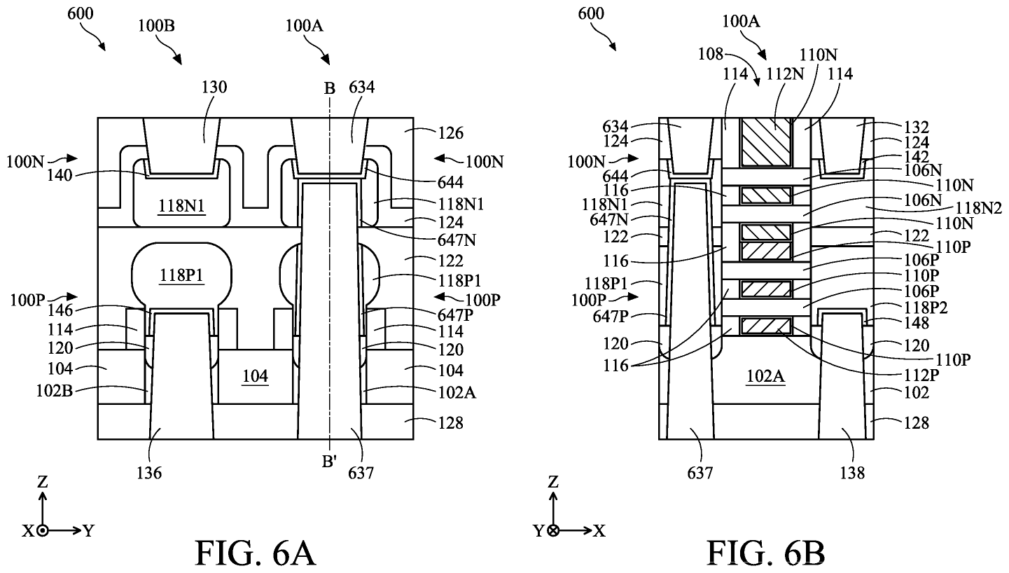

FIG. 6A is a Y-Z cross-sectional view of a semiconductor device 600, in accordance with alternative embodiments of the present disclosure. FIG. 6B is an X-Z cross-sectional view of the semiconductor device 600 along line B-B′ of FIG. 6A, in accordance with alternative embodiments of the present disclosure. The semiconductor device 600 shown in FIGS. 6A and 6B may be similar to the semiconductor device 500 shown in FIGS. 5A and 5B, except the source/drain contacts 534, 537 and the silicide layers 544, 547N, 547P shown in FIGS. 5A and 5B are replaced by source/drain contacts 634, 637 and silicide layers 644, 647N, 647P shown in FIGS. 6A and 6B.

Referring to FIGS. 6A and 6B, similar to the source/drain contact 534 shown in FIGS. 5A and 5B, the source/drain contact 634 extends through the ILD layer 126 and the CESLs 124, and partially extend into the source/drain feature 118N, so as to be in contact with and electrically connected to the source/drain feature 118N, in accordance with some embodiments. In some embodiments, the source/drain contact 634 is in contact with the source/drain feature 118N1 of the CFET 100A, as shown in FIGS. 6A and 6B.

In some embodiments, similar to the silicide layer 544 shown in FIGS. 5A and 5B, the silicide layer 644 is formed on the interface between the source/drain contact 634 and the source/drain feature 118N1 of the CFET 100A, as shown in FIGS. 6A and 6B. That is, the silicide layer 644 is formed on sidewalls and the bottom surface of a portion of the source/drain contact 634 inside the source/drain feature 118N1 of the CFET 100A.

Still referring to FIGS. 6A and 6B, similar to the source/drain contact 537 shown in FIGS. 5A and 5B, the source/drain contact 637 extends through the ILD layer 128, the substrate 102, the bottom isolation layer 120, the source/drain feature 118P, and the ILD layer 122, and partially extend into the source/drain feature 118N, so as to be in contact with and electrically connected to both of the source/drain features 118N and 118P, in accordance with some embodiments. In some embodiments, the source/drain contact 637 is in contact with the source/drain features 118N1 and 118P1 of the CFET 100A, and electrically connects them together, as shown in FIGS. 6A and 6B. Similar to the source/drain contact 537, the source/drain contact 637 may be referred to as backside source/drain contact, bottom source/drain contact, or the backside S/D LI contact.

In some embodiments, similar to the silicide layer 547N shown in FIGS. 5A and 5B, the silicide layer 647N is formed on the interface between the source/drain contact 637 and the source/drain feature 118N1 of the CFET 100A, as shown in FIGS. 6A and 6B. In some embodiments, similar to the silicide layer 547P shown in FIGS. 5A and 5B, the silicide layer 647P is formed on the interface between the source/drain contact 637 and the source/drain feature 118P1 of the CFET 100A, as shown in FIGS. 6A and 6B. That is, the silicide layer 647N is formed on sidewalls and the top surface of a portion of the source/drain contact 637 inside the source/drain feature 118N1 of the CFET 100A. In some embodiments, the material of the silicide layer 647N is different from the material of the silicide layer 647P. In further embodiments, the material of the silicide layer 644 is different from the materials of the silicide layers 647N and 647P.

In some embodiments, the source/drain contact 634 is electrically connected to the source/drain contact 637 through the silicide layer 644 and the silicide layer 647N. In these embodiments, the silicide layer 644 is in direct contact with the silicide layer 647N in the source/drain feature 118N1 of the CFET 100A, as shown in FIGS. 6A and 6B. That is, a horizontal portion of the silicide layer 644 formed on the bottom surface of the source/drain contact 634 is in direct contact with a horizontal portion of the silicide layer 647N formed on the top surface of the source/drain contact 637 in the source/drain feature 118N1 of the CFET 100A.

In some embodiments, the source/drain contact 634 and/or the source/drain contact 637 are connected to signals. Similar to the source/drain contacts 534 and 537 described above, the arrangement of the source/drain contacts 634 and 637 can allow the signal routing to be arranged on the frontside, the backside, or both of the frontside and backside of the semiconductor device 600. As a result, the flexibility for the signal routing can be improved. In some embodiments where the semiconductor device 600 is applied to a SRAM device, the source/drain contacts 634 and 637 may function as the source/drain contacts 534 and 537 in the embodiments where the semiconductor device 500 is applied to the SRAM device.

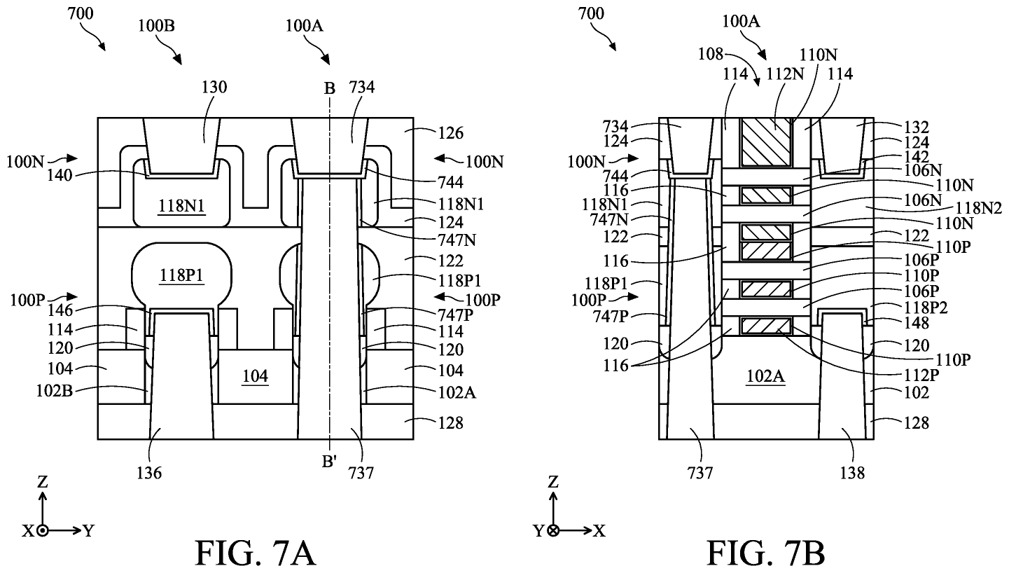

FIG. 7A is a Y-Z cross-sectional view of a semiconductor device 700, in accordance with alternative embodiments of the present disclosure. FIG. 7B is an X-Z cross-sectional view of the semiconductor device 700 along line B-B′ of FIG. 7A, in accordance with alternative embodiments of the present disclosure. The semiconductor device 700 shown in FIGS. 7A and 7B may be similar to the semiconductor device 500 shown in FIGS. 5A and 5B, except the source/drain contacts 534, 537 and the silicide layers 544, 547N, 547P shown in FIGS. 5A and 5B are replaced by source/drain contacts 734, 737 and silicide layers 744, 747N, 747P shown in FIGS. 7A and 7B.

Referring to FIGS. 7A and 7B, similar to the source/drain contact 534 shown in FIGS. 5A and 5B, the source/drain contact 734 extends through the ILD layer 126 and the CESLs 124, and partially extend into the source/drain feature 118N, so as to be in contact with and electrically connected to the source/drain feature 118N, in accordance with some embodiments. In some embodiments, the source/drain contact 734 is in contact with the source/drain feature 118N1 of the CFET 100A, as shown in FIGS. 7A and 7B.

In some embodiments, similar to the silicide layer 544 shown in FIGS. 5A and 5B, the silicide layer 744 is formed on the interface between the source/drain contact 734 and the source/drain feature 118N1 of the CFET 100A, as shown in FIGS. 7A and 7B. That is, the silicide layer 744 is formed on sidewalls and the bottom surface of a portion of the source/drain contact 734 inside the source/drain feature 118N1 of the CFET 100A.

Still referring to FIGS. 7A and 7B, similar to the source/drain contact 537 shown in FIGS. 5A and 5B, the source/drain contact 737 extends through the ILD layer 128, the substrate 102, the bottom isolation layer 120, the source/drain feature 118P, and the ILD layer 122, and partially extend into the source/drain feature 118N, so as to be in contact with and electrically connected to both of the source/drain features 118N and 118P, in accordance with some embodiments. In some embodiments, the source/drain contact 737 is in contact with the source/drain features 118N1 and 118P1 of the CFET 100A, and electrically connects them together, as shown in FIGS. 7A and 7B. Similar to the source/drain contact 537, the source/drain contact 737 may be referred to as backside source/drain contact, bottom source/drain contact, or the backside S/D LI contact.

In some embodiments, similar to the silicide layer 547N shown in FIGS. 5A and 5B, the silicide layer 747N is formed on the interface between the source/drain contact 737 and the source/drain feature 118N1 of the CFET 100A, as shown in FIGS. 7A and 7B. In some embodiments, similar to the silicide layer 547P shown in FIGS. 5A and 5B, the silicide layer 747P is formed on the interface between the source/drain contact 737 and the source/drain feature 118P1 of the CFET 100A, as shown in FIGS. 7A and 7B. That is, the silicide layer 747N is formed on sidewalls of a portion of the source/drain contact 737 inside the source/drain feature 118N1 of the CFET 100A. In some embodiments, the material of the silicide layer 747N is different from the material of the silicide layer 747P. In further embodiments, the material of the silicide layer 744 is different from the materials of the silicide layers 747N and 747P.

In some embodiments, the source/drain contact 734 is electrically connected to the source/drain contact 737 through the silicide layer 744. In these embodiments, the silicide layer 744 is in direct contact with the source/drain contact 737 in the source/drain feature 118N1 of the CFET 100A, as shown in FIGS. 7A and 7B. That is, a horizontal portion of the silicide layer 744 formed on the bottom surface of the source/drain contact 734 is in direct contact with the top surface of the source/drain contact 737 in the source/drain feature 118N1 of the CFET 100A.

In some embodiments, the source/drain contact 734 and/or the source/drain contact 737 are connected to signals. Similar to the source/drain contacts 534 and 537 described above, the arrangement of the source/drain contacts 734 and 737 can allow the signal routing to be arranged on the frontside, the backside, or both of the frontside and backside of the semiconductor device 700. As a result, the flexibility for the signal routing can be improved. In some embodiments where the semiconductor device 700 is applied to a SRAM device, the source/drain contacts 734 and 737 may function as the source/drain contacts 534 and 537 in the embodiments where the semiconductor device 500 is applied to the SRAM device.

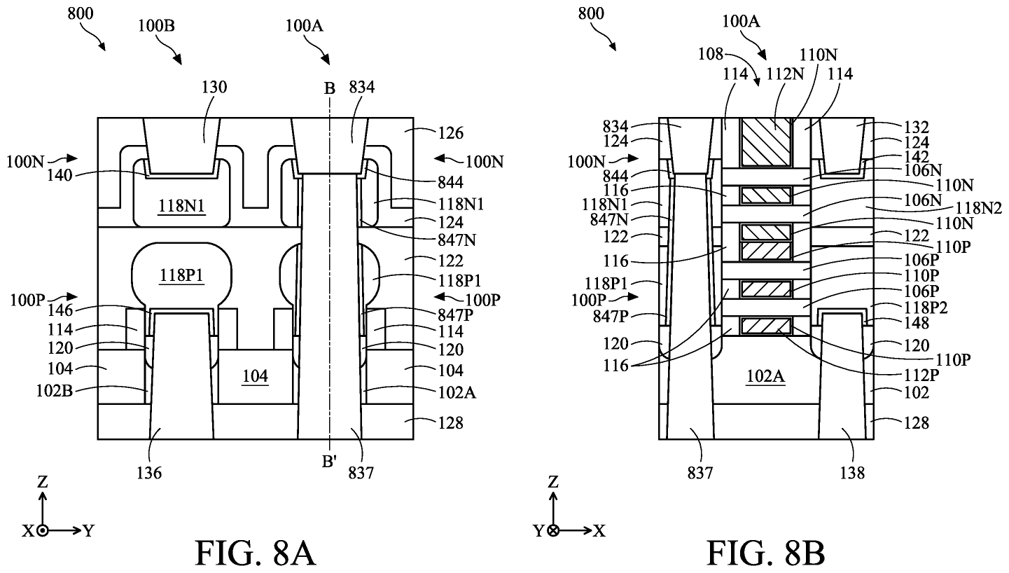

FIG. 8A is a Y-Z cross-sectional view of a semiconductor device 800, in accordance with alternative embodiments of the present disclosure. FIG. 8B is an X-Z cross-sectional view of the semiconductor device 800 along line B-B′ of FIG. 8A, in accordance with alternative embodiments of the present disclosure. The semiconductor device 800 shown in FIGS. 8A and 8B may be similar to the semiconductor device 500 shown in FIGS. 5A and 5B, except the source/drain contacts 534, 537 and the silicide layers 544, 547N, 547P shown in FIGS. 5A and 5B are replaced by source/drain contacts 834, 837 and silicide layers 844, 847N, 847P shown in FIGS. 8A and 8B.

Referring to FIGS. 8A and 8B, similar to the source/drain contact 534 shown in FIGS. 5A and 5B, the source/drain contact 834 extends through the ILD layer 126 and the CESLs 124, and partially extend into the source/drain feature 118N, so as to be in contact with and electrically connected to the source/drain feature 118N, in accordance with some embodiments. In some embodiments, the source/drain contact 834 is in contact with the source/drain feature 118N1 of the CFET 100A, as shown in FIGS. 8A and 8B.

In some embodiments, similar to the silicide layer 544 shown in FIGS. 5A and 5B, the silicide layer 844 is formed on the interface between the source/drain contact 834 and the source/drain feature 118N1 of the CFET 100A, as shown in FIGS. 8A and 8B. That is, the silicide layer 844 is formed on sidewalls of a portion of the source/drain contact 834 inside the source/drain feature 118N1 of the CFET 100A. In some embodiments, the silicide layer 844 is also formed on a portion the bottom surface of the source/drain contact 834, as shown in FIGS. 8A and 8B.

Still referring to FIGS. 8A and 8B, similar to the source/drain contact 537 shown in FIGS. 5A and 5B, the source/drain contact 837 extends through the ILD layer 128, the substrate 102, the bottom isolation layer 120, the source/drain feature 118P, and the ILD layer 122, and partially extend into the source/drain feature 118N, so as to be in contact with and electrically connected to both of the source/drain features 118N and 118P, in accordance with some embodiments. In some embodiments, the source/drain contact 837 is in contact with the source/drain features 118N1 and 118P1 of the CFET 100A, and electrically connects them together, as shown in FIGS. 8A and 8B. Similar to the source/drain contact 537, the source/drain contact 837 may be referred to as backside source/drain contact, bottom source/drain contact, or the backside S/D LI contact.

In some embodiments, similar to the silicide layer 547N shown in FIGS. 5A and 5B, the silicide layer 847N is formed on the interface between the source/drain contact 837 and the source/drain feature 118N1 of the CFET 100A, as shown in FIGS. 8A and 8B. In some embodiments, similar to the silicide layer 847P shown in FIGS. 5A and 5B, the silicide layer 847P is formed on the interface between the source/drain contact 837 and the source/drain feature 118P1 of the CFET 100A, as shown in FIGS. 8A and 8B. That is, the silicide layer 847N is formed on sidewalls of a portion of the source/drain contact 837 inside the source/drain feature 118N1 of the CFET 100A. In some embodiments, the material of the silicide layer 847N is different from the material of the silicide layer 847P. In further embodiments, the material of the silicide layer 844 is different from the materials of the silicide layers 847N and 847P. In some embodiments, since the source/drain contact 837 is formed after the formation of the source/drain contact 834 and the silicide layer 844, the top portion of the source/drain contact 837 is surrounded by the silicide layer 844, as shown in FIGS. 8A and 8B.

In some embodiments, the source/drain contact 834 is electrically connected to the source/drain contact 837 through direct contact. In these embodiments, the source/drain contact 834 is in direct contact with the source/drain contact 837 in the source/drain feature 118N1 of the CFET 100A, as shown in FIGS. 8A and 8B. That is, the bottom surface of the source/drain contact 834 is in direct contact with the top surface of the source/drain contact 837 in the source/drain feature 118N1 of the CFET 100A.

In some embodiments, the source/drain contact 834 and/or the source/drain contact 837 are connected to signals. Similar to the source/drain contacts 534 and 537 described above, the arrangement of the source/drain contacts 834 and 837 can allow the signal routing to be arranged on the frontside, the backside, or both of the frontside and backside of the semiconductor device 800. As a result, the flexibility for the signal routing can be improved. In some embodiments where the semiconductor device 800 is applied to a SRAM device, the source/drain contacts 834 and 837 may function as the source/drain contacts 534 and 537 in the embodiments where the semiconductor device 500 is applied to the SRAM device.

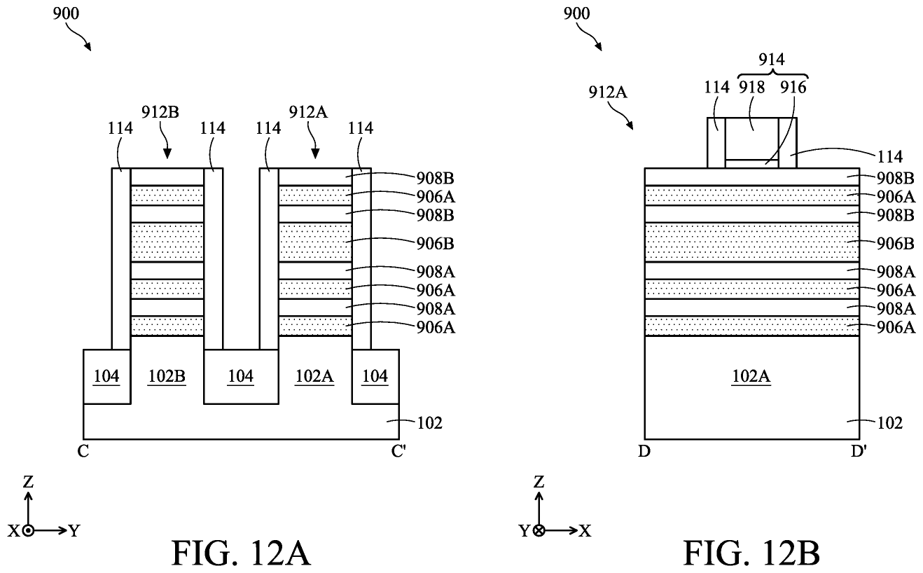

The formation of the semiconductor device (e.g., the semiconductor devices 100-800) are described in detail in below. The formation of the semiconductor device starts from a workpiece 900. FIG. 9 is a perspective view of a workpiece 900 at a fabrication stage, in accordance with some embodiments of the present disclosure. FIGS. 10, 11A, 12A, 13A, 14A, 15A, 16A, 17A, 18A, 19A, 22A, 23A, 24A, 25A, 26A, 27A, 28A, 29A, 30A, 31A, and 32A are Y-Z cross-sectional views of the workpiece 900 at various fabrication stages along line C-C′ of FIG. 9, in accordance with some embodiments of the present disclosure. FIGS. 12B, 13B, 14B, 15B, 16B, 17B, 18B, 19B, 20A, 21A, 22B, 23B, 24B, 25B, 26B, 27B, 28B, 29B, 30B, 31B, and 32B are X-Z cross-sectional views of the workpiece 900 at various fabrication stages along line D-D′ of FIG. 9, in accordance with some embodiments of the present disclosure. FIGS. 11B, 20B, and 21B are Y-Z cross-sectional views of the workpiece 900 at various fabrication stages along line E-E′ of FIG. 9, in accordance with some embodiments of the present disclosure.

Referring to FIG. 9, the workpiece 900 is provided. The workpiece 900 includes a substrate 102 and a stack 904 over the substrate 102. In some embodiments, the substrate 102 contains a semiconductor material, such as bulk silicon (Si). In some other embodiments, the substrate 102 may include other semiconductors such as Ge, SiGe, or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions, such as n-type well regions doped with an n-type dopant (e.g., phosphorus (P) or arsenic (As)) or p-type well regions doped with a p-type dopant (e.g., boron (B)), for forming different types of devices. The n-type well regions and the p-type well regions may be formed by using ion implantation or thermal diffusion.

In some embodiments, the stack 904 includes semiconductor layers 906 (including semiconductor layers 906A and a semiconductor layer 906B) and 908 (including semiconductor layers 908A and 908B), and the semiconductor layers 906 and 908 are stacked in an alternating manner in the Z-direction. In some embodiments, the semiconductor layer 906B is form vertically between a group of semiconductor layers 908A and a group of semiconductor layers 908B. In some embodiments, a thickness of the semiconductor layer 906B is greater than the thickness of the semiconductor layers 906A, as shown in FIG. 9.

In some embodiments, the thickness of the semiconductor layers 908A is greater than the semiconductor layers 908B by a difference in a range from about 0.5 nm to about 5 nm. In other embodiments, the thicknesses of the semiconductor layers 908A and 908B are the same. In yet some embodiments, the thickness of the topmost semiconductor layer 908B is greater than the thickness of the other semiconductor layers 908B. In some embodiments, the thickness of the bottommost semiconductor layer 908A is greater than the thickness of the other semiconductor layers 908A.

The semiconductor layers 908 may include a semiconductor material, such as silicon, germanium, silicon carbide, silicon phosphide, gallium arsenide, gallium phosphide, indium phosphide, indium arsenide, and/or indium antimonide, SiGe, SiPC, GaAsP, AlInAs, AlGaAs, GaInAs, GaInP, and/or GaInAsP. In some embodiments, the semiconductor layers 908B include silicon for n-type transistors (i.e., NFETs 100N of the CFETs 100A and 100B). In some embodiments, the semiconductor layers 908A include silicon germanium for p-type transistors (i.e., PFETs 100P of the CFETs 100A and 100B). In some embodiments, the semiconductor layers 908 are all made of silicon, and the type of the transistors depend on a work function metal layer wrapped around the nanostructures 106 (which are formed from the semiconductor layers 908).

The semiconductor layers 906 and the semiconductor layers 908 may have different semiconductor compositions. In some embodiments, semiconductor layers 906 are formed of SiGe and the semiconductor layers 908 are formed of Si. In these embodiments, the additional germanium content in the semiconductor layers 906 allow selective removal or recess of the semiconductor layers 906 without substantial damages to the semiconductor layers 908, so that the semiconductor layers 906 are also referred to as sacrificial layers.

In some embodiments, the semiconductor layers 906 and 908 are epitaxially grown over or on the substrate 102 using an epitaxial growth such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 906 and 908 are grown alternatingly, one-after-another, to form the stack 904.

The two semiconductor layers 908A are used for the PFETs 100P of the CFETs 100A and 100B and the two semiconductor layers 908B are used for the NFETs 100N of the CFETs 100A and 100B. It should be noted that four layers of the semiconductor layers 906 and four layers of the semiconductor layers 908 are alternately and vertically arranged (or stacked) as shown in FIG. 9, which are for illustrative purposes only and not intended to be limiting beyond what is specifically recited in the claims. The number of the semiconductor layers depends on the desired number of channel members for the semiconductor device.

Referring to FIG. 10, the substrate 102 and the stack 904 are then patterned to form fin structures 912A and 912B (may be collectively referred to as fin structures 912) over the substrate 102. For patterning purposes, the stack 904 may further include a hard mask layer 910 over the topmost semiconductor layer. The hard mask layer 910 may be a single layer structure or a multi-layer structure. In some embodiments, the hard mask layer 910 is a single layer structure and includes a silicon germanium layer. In some embodiments, the hard mask layer 910 is a multi-layer structure and includes a silicon nitride layer and a silicon oxide layer over the silicon nitride layer. In other embodiments, the hard mask layer 910 is a multi-layer structure and includes a silicon germanium layer and a silicon layer over the silicon germanium layer.

As shown in FIG. 10, each of the fin structures 912 includes a base fin (i.e., the base portions 102A and 102B of the substrate 102 discussed above) formed from the substrate 102 and a stack portion formed from the stack 904 over the base fin, in accordance with some embodiments. The stack portion of each of the fin structures 912 includes the semiconductor layers 906 and 908 that are alternately stacked in the Z-direction. In some embodiments, the fin structures 912A and 912B extend in the X-direction, and are arranged in the Y-direction.

The fin structures 912 may be patterned using suitable processes including double-patterning or multi-patterning processes. For example, in some embodiments, a material layer is formed over the stack 904 and patterned using a photolithography process. Spacers are formed alongside the patterned material layer using a self-aligned process. The material layer is then removed, and the remaining spacers, or mandrels, may then be used to pattern the fin structures 912 by etching the stack 904 and the substrate 102. The etching process may include dry etching, wet etching, reactive ion etching (RIE), and/or other suitable processes.

Still referring to FIG. 10, isolation structures 104 are formed, in accordance with some embodiments. After the fin structures 912 are formed, the isolation structures 104 are formed over the substrate 102. In some embodiments, the isolation structures 104 extend in the X-direction (not shown) and are arranged with the fin structures 912 in the Y-direction. In other words, the isolation structures 104 are formed on opposite sides of the fin structures 912 in the Y-direction. In some aspects, the isolation structures 104 are formed around the fin structures 912.

The isolation structures 104 may include different structures, such as shallow trench isolation (STI) structures, deep trench isolation (DTI) structures, and/or local oxidation of silicon (LOCOS) structures. In some embodiments, STI structures include a multi-layer structure that fills the trenches, such as a silicon nitride comprising layer disposed over a thermal oxide comprising liner layer. In other embodiments, STI structures include a dielectric layer disposed over a doped liner layer (including, for example, boron silicate glass (BSG) or phosphosilicate glass (PSG)). In certain embodiments, STI structures include a bulk dielectric layer disposed over a liner dielectric layer, wherein the bulk dielectric layer and the liner dielectric layer include materials depending on design requirements.

In some embodiments, a dielectric material for the isolation structures 104 is first deposited over the workpiece 900. In some embodiments, the dielectric material may include silicon oxide, silicon nitride, silicon oxynitride, FSG, low-k dielectrics, other suitable materials (e.g., including silicon, oxygen, nitrogen, carbon, or other suitable isolation constituent), or combinations thereof. In various embodiments, the dielectric material may be deposited using a deposition process, such as CVD, subatmospheric CVD (SACVD), FCVD, ALD, spin-on coating, or other suitable process. The deposited dielectric material is then thinned and planarized, for example by a CMP process. The planarized dielectric material is further recessed by a dry etching process, a wet etching process, and/or a combination thereof to form the isolation structures 104. In some embodiments, the stack portions of the fin structures 912 rise above the isolation structures 104 while the base portions 102A and 102B are surrounded by the isolation structures 104, as shown in FIG. 10. In other words, the top surfaces of the substrate 102 is higher than top surfaces of the isolation structures 104.

Referring to FIGS. 11A and 11B, the hard mask layer 910 is removed and a dummy gate structure 914 is formed over the fin structures 912 and the isolation structures 104, in accordance with some embodiments. The dummy gate structure 914 may be configured to extend along the Y-direction and wrap around top surfaces and side surfaces of the fin structures 912. In some embodiments, to form the dummy gate structure 914, a dummy gate dielectric material for a dummy gate dielectric layer 916 is first formed over fin structures 912 and over the isolation structures 104. In some embodiments, the dummy gate dielectric material may include, for example, a dielectric material such as a nitride (e.g., silicon nitride, silicon oxynitride), a carbide (e.g., silicon carbide), an oxide (e.g., silicon oxide), or other suitable material.

Then, in some embodiments, a dummy gate electrode material for a dummy gate electrode 918 is formed over the dummy gate dielectric material. The dummy gate electrode material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., PVD, CVD, PECVD, and ALD).

After the formation of the dummy gate electrode material and the dummy gate dielectric material, photolithography and etching processes may be performed to remove portions of the dummy gate electrode material and the dummy gate dielectric material, thereby forming the dummy gate structure 914 having the dummy gate electrode 918 and the dummy gate dielectric layer 916. The dummy gate structure 914 may undergo a gate replacement process through subsequent processing to form metal gates, such as a high-k metal gate, as discussed in greater detail below.

Referring to FIGS. 12A and 12B, after forming of the dummy gate structure 914, the gate spacers 114 are formed on sidewalls of the dummy gate structure 914, and over the top surfaces and on the sidewalls of the fin structures 912, in accordance with some embodiments. In some embodiments, the gate spacers 114 are formed on opposite sidewalls of the fin structures 912, as shown in FIG. 12A, and formed on opposite sidewalls of the dummy gate structures 914, as shown in FIG. 12B.

The gate spacers 114 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 114 may include a single layer or a multi-layer structure.

In some embodiments, the gate spacers 114 may be formed by conformally depositing a spacer layer (containing the dielectric material) over the isolation structures 104, the fin structures 912, and the dummy gate structure 914, followed by an anisotropic etching process to remove top portions of the spacer layer from the top surfaces of the isolation structures 104, the fin structures 912, and the dummy gate structure 914. After the anisotropic etching process, portions of the spacer layer on the sidewall surfaces of the fin structures 912 and the dummy gate structure 914 substantially remain and become the gate spacers 114. In some embodiments, the anisotropic etching process is a dry (e.g., plasma) etching process. Additionally or alternatively, the formation of the gate spacers 114 may also involve chemical oxidation, thermal oxidation, CVD, PVD, ALD, HDPCVD, MOCVD, RPCVD, PECVD, LPCVD, ALCVD, APCVD, FCVD, and/or other suitable methods.

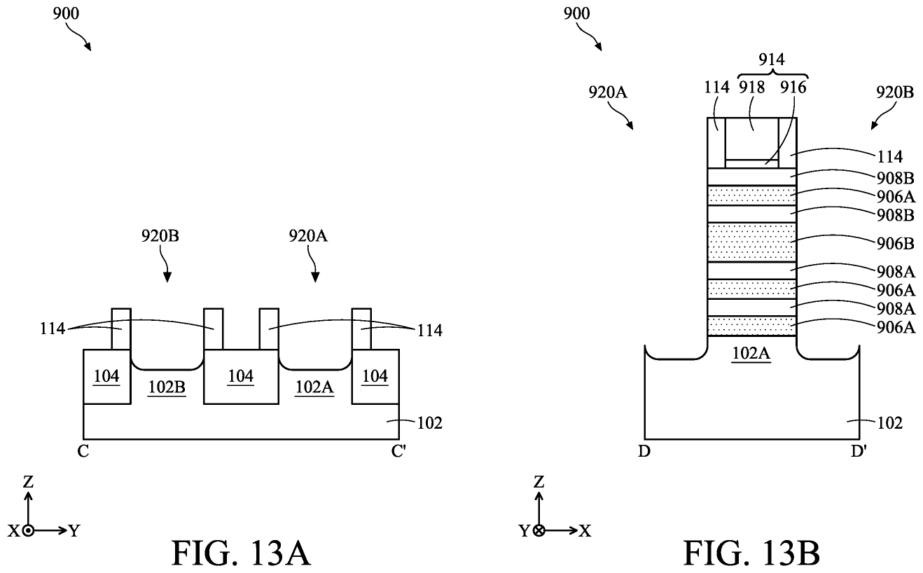

Referring to FIGS. 13A and 13B, the fin structures 912 are recessed to form source/drain trenches 920 in the fin structures 912, in accordance with some embodiments. In some embodiments, in each of the fin structures 912A and 912B, the source/drain trenches 920 include a source/drain trench 920A and a source/drain trench 920B that are on opposite sides of the dummy gate structure 914 in the X-direction. The source/drain trenches 920 may be formed by performing one or more etching processes to remove portions of the semiconductor layers 906 and 908 and the substrate 102 that do not vertically overlap or be covered by the dummy gate structure 914 and the gate spacers 114. In some embodiments, a single etchant may be used to remove the semiconductor layers 906 and 908 and the substrate 102. In other embodiments, multiple etchants may be used to perform the etching process. In some embodiments, portions of the gate spacers 114 on opposite sidewalls of the fin structures 912 in the Y-direction are removed, as shown in FIG. 13A. In these embodiments, the height of the gate spacers 114 on the opposite sidewalls of the fin structures 912 in the Y-direction are reduced.

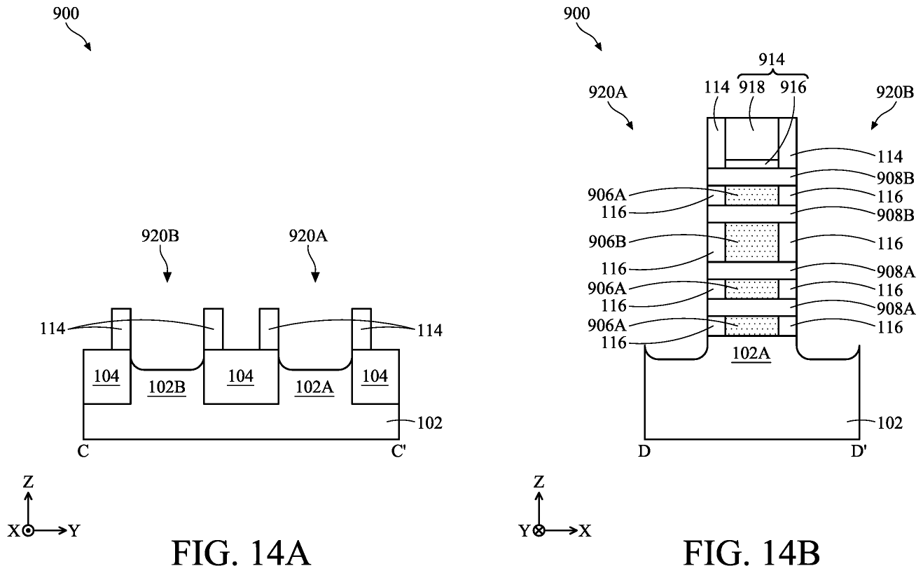

Referring to FIGS. 14A and 14B, the inner spacers 116 are formed between the semiconductor layers 908 as well as between the semiconductor layer 908 and the substrate 102, in accordance with some embodiments. In some embodiments, the semiconductor layers 906 (including the semiconductor layers 906A and 906B) exposed in the source/drain trenches 920 are partially recessed through a selective etching process, and the semiconductor layers 908 are not etched. More specifically, the selective etching process is performed that selectively etches the side portions of the semiconductor layers 906 below the gate spacers 114 through the source/drain trenches 920, with minimal etching (or substantially no etching) of the semiconductor layers 908 and the substrate 102. After the selective etching process, inner spacer recesses are vertically formed between the semiconductor layers 908 as well as between the semiconductor layers 908 and the substrate 102, below the gate spacers 114. The selective etching process is configured to laterally etch (e.g., along the X-direction) the semiconductor layers 906 below the gate spacers 114. The selective etching process may be a dry etching process, a wet etching process, other suitable etching process, or a combination thereof.

Next, in some embodiments, a spacer layer is conformally formed into the source/drain trenches 920 and the inner spacer recesses. More specifically, a deposition process is performed to form the spacer layer into the source/drain trenches 920 and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer partially (and, in some embodiments, completely) fills the source/drain trenches 920 and fully fills the inner spacer recesses. The deposition process is configured to ensure that the spacer layer fills the inner spacer recesses between the semiconductor layers 908 as well as between the semiconductor layer 908 and the substrate 102 under the gate spacers 114. Furthermore, the spacer layer is also conformally formed on the gate spacers 114 and the isolation structures 104.

The spacer layer may include a material that is different than the material of the semiconductor layers 908 and the material of the gate spacers 114 to achieve desired etching selectivity during the etching process. In some embodiments, the spacer layer include a dielectric material that includes silicon, oxygen, carbon, nitrogen, other suitable material, or combinations thereof (e.g., silicon oxide (SiO₂), SiON, SiOC, SiCN, SiOCN). In some embodiments, the spacer layer include a low-k dielectric material, such as those described herein. In some embodiments, the spacer layer includes a dielectric material having higher k value (dielectric constant) than the gate spacers 114. In other embodiments, the spacer layer includes a dielectric material having lower k value than the gate spacers 114.

Then, in some embodiments, the inner spacers 116 are formed to fill the inner spacer recesses between the semiconductor layers 908 as well as between the semiconductor layer 908 and the substrate 102. More specifically, an etching process is performed to selectively etch the spacer layer to form the inner spacers 116 with minimal etching (or substantially no etching) of the semiconductor layers 908, the substrate 102, the dummy gate structure 914, and the gate spacers 114. The etching process may be an anisotropic etching process, such that portions of the spacer layer that do not vertically overlap or be covered by the dummy gate structure 914 and the gate spacers 114 are removed. The spacer layer on the gate spacers 114 and the isolation structures 104 are removed.

In some embodiments, sidewalls of the inner spacers 116 are aligned to the sidewalls of the gate spacers 114 and the semiconductor layers 908. Therefore, the inner spacers 116 are formed on opposite sides of the dummy gate structure 914. In some embodiments, the inner spacers 116 are also vertically between the semiconductor layers 908 as well as between the semiconductor layer 908 and the substrate 102. In some embodiments, the thickness of the gate spacers 114 and the thickness of the inner spacers 116 are the same in the X-direction. In other embodiments, the thickness of the gate spacers 114 is greater than the thickness of the inner spacers 116 in the X-direction for capacitance reduction between source/drain contacts (e.g., the source/drain contacts 118N/118P) and the gate structure (e.g., the gate structure 108).

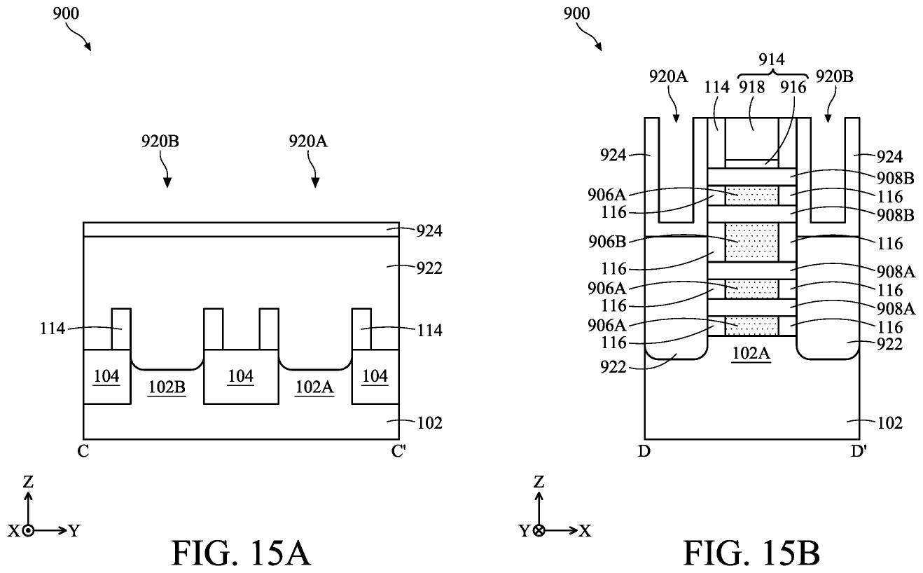

Referring to FIGS. 15A and 15B, polymer layers 922 and cover spacers 924 are formed in the source/drain trenches 920, in accordance with some embodiments. More specifically, the polymer layers 922 are first formed in lower parts of the source/drain trenches 920 to cover the top surfaces of the substrate 102 and the sidewalls of the semiconductor layers 908A (which are used for the PFET of the CFET, such as the PFETs 100P of the CFETs 100A and 100B discussed above) and the inner spacers 116 (which are between the semiconductor layers 908A) exposed in the source/drain trenches 920. In some embodiments, top surfaces of the polymer layers 922 are lower than the semiconductor layers 908B. In some embodiments, the polymer layers 922 is also formed on the gate spacers 114 and the isolation structures 104, as shown in FIG. 15A.

After forming the polymer layers 922, the cover spacers 924 are conformally formed over the polymer layers 922 and on the sidewalls of the semiconductor layers 908B (which are used for the NFET of the CFET, such as the NFETs 100N of the CFETs 100A and 100B discussed above), the gate spacers 114, and the inner spacers 116 (which are between the semiconductor layers 908B). The polymer layers 922 may be formed of fluorine-containing polymer and its molecular structure includes silicon (Si), carbon (C), nitrogen (N), or fluorine (F). In some embodiments, the polymer layers 922 include fluorinated silicone or fluorinated polysilane. In some embodiments, the polymer layers 922 are spin-on-carbon layers. The polymer layers 922 may be deposited using CVD, flowable CVD (FCVD), or spin-on coating. The cover spacers 924 may include aluminum oxide (Al₂O₃).

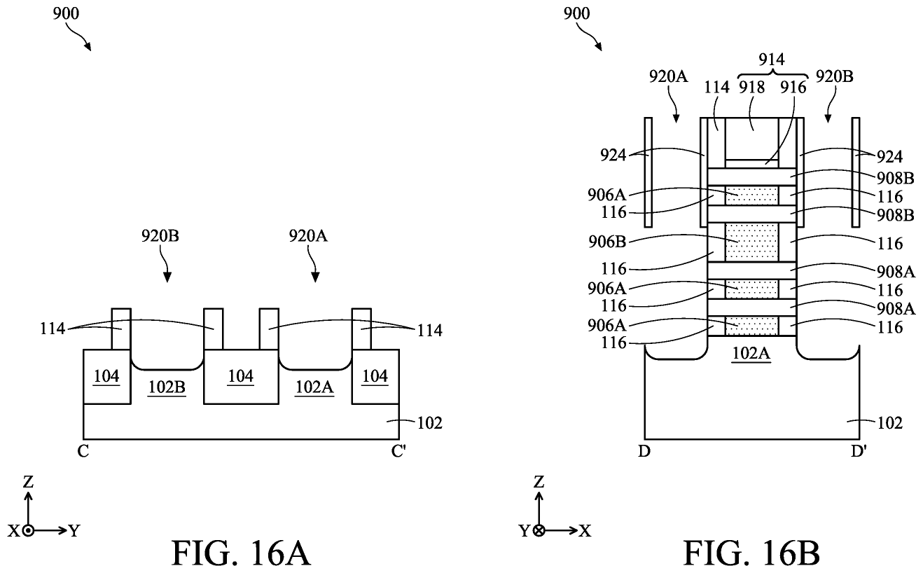

Referring to FIGS. 16A and 16B, the polymer layers 922 and horizontal portions of the cover spacers 924 are removed, in accordance with some embodiments. More specifically, an anisotropic etching process is performed to remove the horizontal portions of the cover spacers 924 to exposed top surfaces of the polymer layers 922, and then a selective etching process is performed to remove the polymer layers 922. In some embodiments, vertical portions of the cover spacers 924 are partially removed or trimmed, but the vertical portions of the cover spacers 924 still cover the sidewalls of the gate spacers 114 and the semiconductor layers 908B, as shown in FIG. 16B. The selective etching process is performed that selectively etches the polymer layers 922 below the cover spacers 924 through the source/drain trenches 920, with minimal etching (or substantially no etching) of the semiconductor layers 908A, the substrate 102, and the inner spacers 116. The selective etching process is a dry etching process, a wet etching process, other suitable etching process, or combinations thereof.

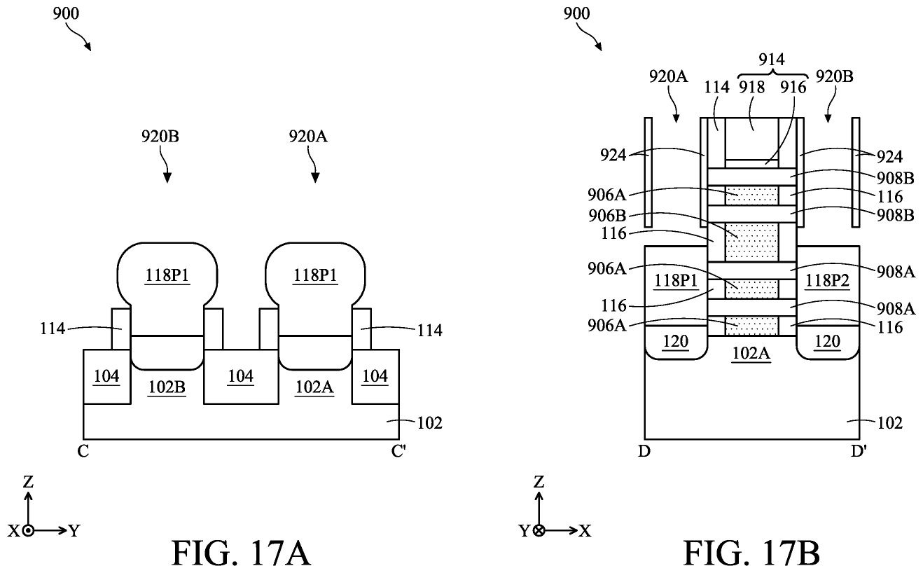

Referring to FIGS. 17A and 17B, after removing the polymer layers 922, the bottom isolation layers 120 and the source/drain features 118P are formed in the lower parts of the source/drain trenches 920 and below the cover spacers 924, in accordance with some embodiments. In some embodiments, the bottom isolation layers 120 are formed over the substrate 102 exposed in the source/drain trenches 920, and the source/drain features 118P are formed over the bottom isolation layers 120. In these embodiments, the bottom isolation layers 120 are vertically between and in contact with the source/drain features 118P and the substrate 102 in the Z-direction, and on opposite sides of the dummy gate structure 914 in the X-direction.

In some embodiments, the top surfaces of the bottom isolation layers 120 are higher than the topmost surfaces of the substrate 102 (i.e., the top surfaces of the base portions 102A and 102B) to ensure that the bottom isolation layers 120 separate the source/drain features 118P from the substrate 102. In some embodiments, the dielectric material of the bottom isolation layers 120 may include silicon nitride (Si₃N₄), silicon oxide (SiO₂), SiC, SiOC, SION, SiCN, SiOCN, high-k dielectrics, other suitable materials, or combinations thereof. In some embodiments, the bottom isolation layers 120 may be deposited by CVD, PVD, ALD, HDPCVD, MOCVD, RPCVD, PECVD, LPCVD, ALCVD, APCVD, other suitable methods, or combinations thereof.

In some embodiments, the source/drain features 118P are formed on opposite sides of the dummy gate structure 914 in the X-direction. In some embodiments, source/drain features 118P1 and 118P2 are formed on opposite sides of the dummy gate structure 914, and in the source/drain trenches 920A and 920B respectively, as shown in FIG. 17B. In some embodiments, the source/drain features 118P are connected to and in contact with the semiconductor layers 908A. In other words, the source/drain features 118P are attached to opposite sides of the first group of semiconductor layers 908 (i.e., the semiconductor layers 908A). In some embodiments, the semiconductor layers 908A connect one source/drain feature 118P to another source/drain feature 118P. In some embodiments, the source/drain features 118P may have top surfaces that extend higher than top surfaces of the topmost semiconductor layers 908A (e.g., in the Z-direction). In other embodiments, the top surfaces of the source/drain features 118P substantially level with the top surfaces of the topmost semiconductor layers 908A. In some embodiments, the top surfaces of the source/drain features 118P are lower than the bottom surfaces of the cover spacers 924 and the semiconductor layers 908B.

In some embodiments, the source/drain features 118P may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. The source/drain features 118P are grown from the semiconductor layers 908A rather than the semiconductor layers 908B, the bottom isolation layers 120, and the substrate 102, it is because that the cover spacers 924 cover the sidewalls of the semiconductor layers 908B, and the bottom isolation layers 120 cover the surface of the substrate 102.

In some embodiments, the source/drain features 118P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 118P may be doped with p-type dopants (e.g., boron (B), indium (In), other p-type dopant, or a combination thereof) and have a doping concentration in a range from about 1×10¹⁹/cm³ to 6×10²⁰/cm³. In some embodiments, the source/drain features 118P used for the PFETs of the CFETs (e.g., the PFETs 100P of the CFETs 100A and 100B shown in FIGS. 1A to 8B) may be referred to as p-type source/drain features. The source/drain features 118P may be doped in-situ or ex-situ. One or more annealing processes may be performed to activate the dopants in the source/drain features 118P. The annealing processes may include rapid thermal annealing (RTA) and/or laser annealing processes.

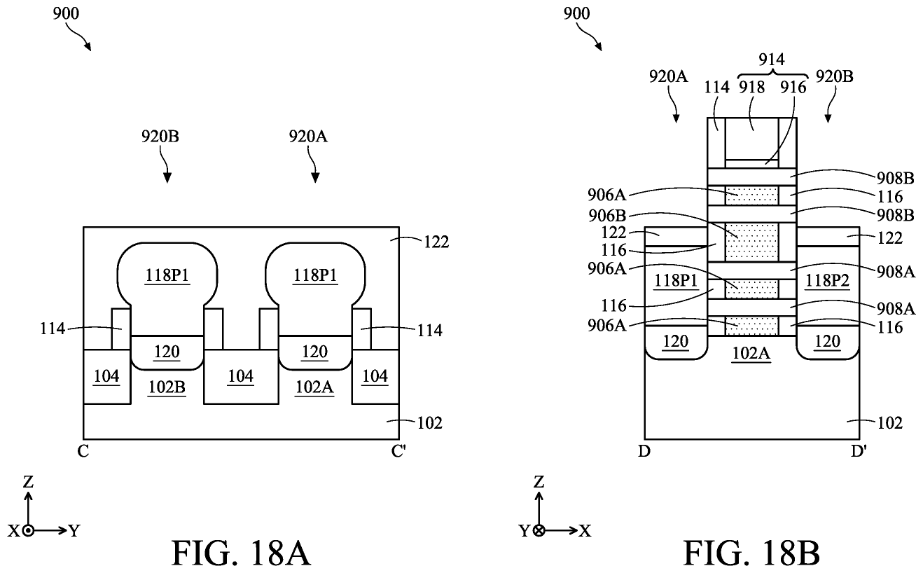

Referring to FIGS. 18A and 18B, the cover spacers 924 are removed through a selective etching process, and then the ILD layer 122 is formed in the source/drain trenches 920 and over the substrate 102, the isolation structures 104, and the source/drain features 118P, in accordance with some embodiments. In some embodiments, the selective etching process is performed that selectively etches the cover spacers 924 over the source/drain features 118P through the source/drain trenches 920, with minimal etching (or substantially no etching) of the semiconductor layers 908B, the gate spacers 114, and the inner spacers 116. The selective etching process may be a dry etching process, a wet etching process, other suitable etching process, or combinations thereof.

After removing the cover spacers 924, the ILD layer 122 is then formed over the substrate 102, the isolation structures 104, and the source/drain features 118P and between the spaces between the source/drain features 118P. In some embodiments, the ILD layer 122 may be formed by CVD, PVD, ALD, HDPCVD, MOCVD, RPCVD, PECVD, LPCVD, ALCVD, APCVD, FCVD, or other suitable methods. Then, the ILD layer 122 over the source/drain features 118P are recessed by performing one or more photolithography and etching processes, so that the sidewalls of the semiconductor layers 908B over the source/drain features 118P are exposed.

In some embodiments, the ILD layer 122 may include tetraethylorthosilicate (TEOS) formed oxide, un-doped silicate glass, or doped silicon oxide such as borophosphosilicate glass (BPSG), fluoride-doped silica glass (FSG), PSG, BSG, low-k dielectric materials, other suitable dielectric materials, or combinations thereof. Exemplary low-k dielectric materials include carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric materials, or combinations thereof.

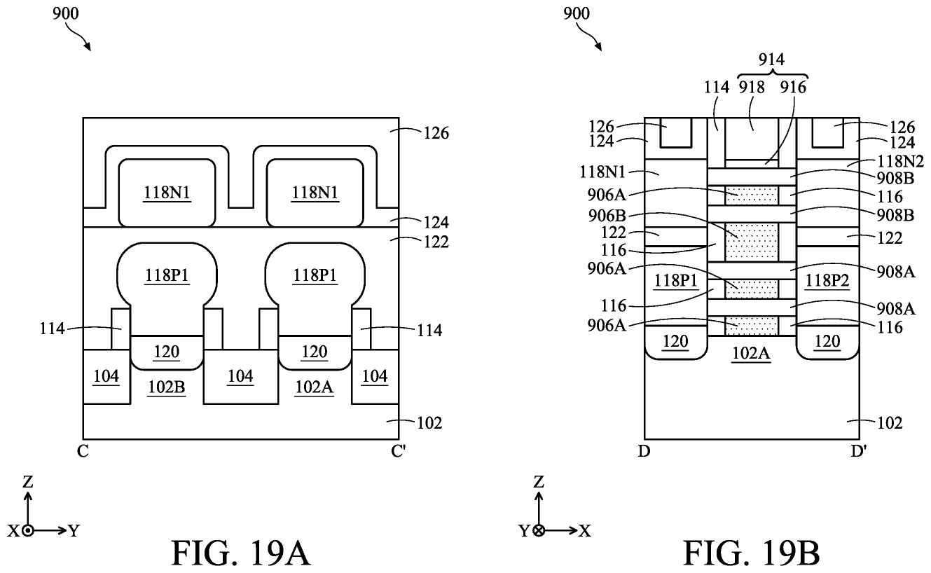

Referring to FIGS. 19A and 19B, the source/drain features 118N are formed in the source/drain trenches 920, in accordance with some embodiments. In some embodiments, the source/drain features 118N are formed over the ILD layer 122 in the source/drain trenches 920. The source/drain features 118N are also formed on opposite sides of the dummy gate structure 914 in the X-direction. In some embodiments, source/drain features 118N1 and 118N2 are formed on opposite sides of the dummy gate structure 914, and over the source/drain features 118P1 and 118P2 respectively, as shown in FIG. 19B. In other words, the source/drain features 118N1 and 118N2 vertically overlaps the source/drain features 118P1 and 118P2, respectively. In some embodiments, the source/drain features 118N are connected to and in contact with the semiconductor layers 908B. In other words, the source/drain features 118N are attached to opposite sides of the second group of semiconductor layers 908 (i.e., the semiconductor layers 908B). In some embodiments, the semiconductor layers 908B connect one source/drain feature 118N to another source/drain feature 118N.

In some embodiments, the source/drain features 118N may have top surfaces that extend higher than top surfaces of the topmost semiconductor layers 908B (e.g., in the Z-direction). In other embodiments, the top surfaces of the source/drain features 118N are substantially level with the top surfaces of the topmost semiconductor layers 908B. In some embodiments, the bottom surfaces of the source/drain features 118N are lower than bottom surfaces of the bottommost semiconductor layers 908B. In other embodiments, the bottom surfaces of the source/drain features 118N are substantially level with the bottom surfaces of the bottommost semiconductor layers 908B.

In some embodiments, the source/drain features 118N may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. The source/drain features 118N are grown from the semiconductor layers 908B.

In some embodiments, the source/drain features 118N may include epitaxially-grown material selected from a group consisting of SiP, SiC, SiPC, SiAs, Si, or a combination thereof. In some embodiments, the epitaxially-grown material of the source/drain features 118N may be doped with n-type dopants (e.g., phosphorus (P), arsenic (As), other n-type dopant, or a combination thereof) and have a doping concentration in a range from about 2×10¹⁹/cm³ to 3×10²¹/cm³. In some embodiments, the source/drain features 118N used for the NFETs of the CFETs (e.g., the NFETs 100N of the CFETs 100A and 100B shown in FIGS. 1A to 8B) may be referred to as n-type source/drain features. The source/drain features 118N may be doped in-situ or ex-situ. One or more annealing processes may be performed to activate the dopants in the source/drain features 118N. The annealing processes may include RTA and/or laser annealing processes.

Still referring to FIGS. 19A and 19B, the CESLs 124 are formed over the source/drain features 118N and the ILD layer 122, and the ILD layer 126 is formed over the CESLs 124 to fill the space between the source/drain features 118N, in accordance with some embodiments. In some embodiments, the CESLs 124 are conformally formed on the sidewalls of the gate spacers 114. In some embodiments, the CESLs 124 are also conformally formed on the top surfaces and the sidewalls of the source/drain features 118N. In some embodiments, the CESLs 124 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 124 may be formed by CVD, PVD, ALD, HDPCVD, MOCVD, RPCVD, PECVD, LPCVD, ALCVD, APCVD, FCVD, or other suitable methods.

The ILD layer 126 is formed over and between the CESLs 124 to fill the space between the CESLs 124 and in the source/drain trenches 920. In some embodiments, the ILD layer 126 includes a material that is different than the CESLs 124. In some embodiments, the ILD layer 126 may include TEOS formed oxide, un-doped silicate glass, or doped silicon oxide such as BPSG, FSG, PSG, BSG, low-k dielectric materials, other suitable dielectric materials, or combinations thereof. The ILD layer 126 may be formed by CVD, PVD, ALD, HDPCVD, MOCVD, RPCVD, PECVD, LPCVD, ALCVD, APCVD, FCVD, or other suitable methods. After forming the CESLs 124 and the ILD layer 126, a CMP process is performed to reduce heights of the CESLs 124 and the ILD layer 126 until top surface of the dummy gate electrode 918 of the dummy gate structure 914 is exposed.

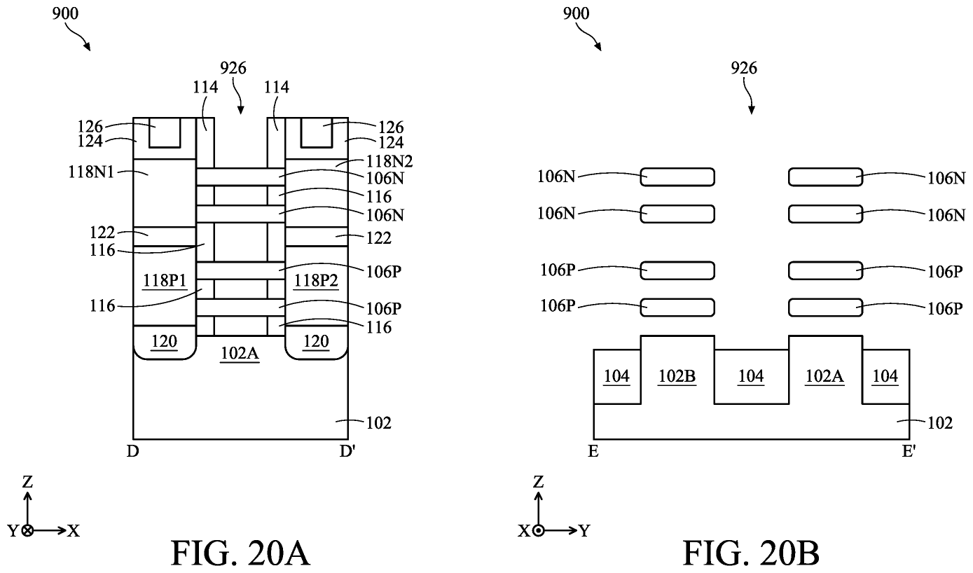

Referring to FIGS. 20A and 20B, the dummy gate structure 914 are selectively removed through any suitable photolithography and etching processes, in accordance with some embodiments. In some embodiments, the photolithography process may include forming a photoresist layer (resist), exposing the resist to a pattern, performing a post-exposure bake process, and developing the resist to form a masking element, which exposes a region including the dummy gate structure 914. Then, the dummy gate structure 914 is selectively etched through the masking element. The gate spacers 114 may be used as the masking element or a part thereof. Etch selectivity may be achieved by selecting appropriate etching chemicals, and the dummy gate structure 914 may be removed without substantially affecting the CESLs 124 and the ILD layer 126. The removal of the dummy gate structure 914 creates a gate trench 926. The gate trench 926 exposes the top surfaces of the topmost semiconductor layers 908B that underlie the dummy gate structure 914.

Still referring to FIGS. 20A and 20B, the semiconductor layers 906 are selectively removed through the gate trench 926, using a wet or dry etching process for example, in accordance with some embodiments. After the semiconductor layers 906 are selectively removed, the semiconductor layers 908A and 908B are exposed in the gate trench 926 to form the nanostructures 106P and 106N stacked on top of each other. Specifically, the nanostructures 106P (the semiconductor layers 908A) are stacked vertically in the Z-direction, and the nanostructures 106N (the semiconductor layers 908B) are directly over the nanostructures 106P and are stacked vertically in the Z-direction. This process may be referred to as a wire release process, a nanowire release process, a nanosheet release process, a nanowire formation process, a nanosheet formation process, or a wire formation process.

In some embodiments, the thicknesses of nanostructures 106 in the NFET and the PFET (e.g., the NFETs 100N and the PFETs 100P of the CFETs 100A and 100B shown in FIGS. 1A to 8B) in the Z-direction are different. For example, a thickness of the nanostructure 106P may be greater than a thickness of the nanostructure 106N in the Z-direction, alternatively, the thickness of the nanostructure 106P may be smaller than that of the nanostructure 106N in the Z-direction. In some embodiments, the difference in thickness between the nanostructure 106P and the nanostructure 106N is in a range from about 0.5 nm to about 5 nm.

In some embodiments, the pitch between the nanostructures 106P (i.e., the distance from the top surface of the lower nanostructure 106P to the bottom surface of the upper nanostructure 106P) is different from the pitch between the nanostructures 106N (i.e., the distance from the top surface of the lower nanostructure 106N to the bottom surface of the upper nanostructure 106N). In some embodiments, the difference between the pitch of the nanostructures 106P and the pitch of the nanostructures 106N is in a range from about 0.5 nm to about 5 nm. In some embodiments, the length of the nanostructures 106P is greater than the length of the nanostructures 106N in the X-direction. In some embodiments, the difference between the length of the nanostructures 106P and the length of the nanostructures 106N is in a range from about 0.5 nm to about 5 nm.

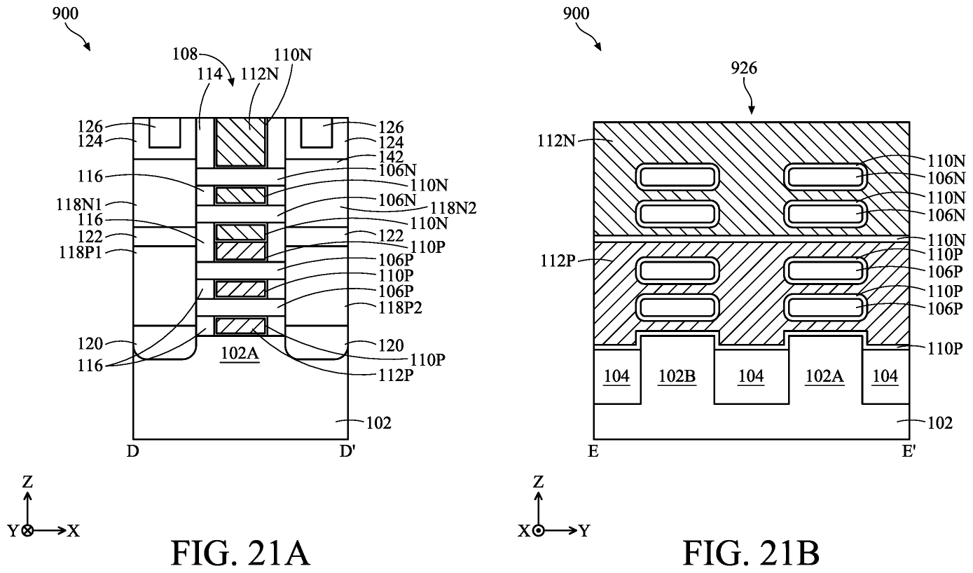

Referring to FIGS. 21A and 21B, the gate structure 108 including the gate dielectric layers 110P, 110N and the gate electrode layers 112P, 112N is formed, in accordance with some embodiments. In some embodiments, the gate dielectric layer 110P and the gate electrode layer 112P are formed in the gate trench 926 to wrap around each of the nanostructures 106P and 106N (the semiconductor layers 908A and 908B). In some embodiments, the gate dielectric layer 110P is wrapped around each of the nanostructures 106P and 106N, and the gate electrode layer 112P is wrapped around the gate dielectric layer 110P and each of the nanostructures 106P and 106N. Additionally, the gate dielectric layer 110P is also formed on the sidewalls of the inner spacers 116 and the gate spacers 114, as well as over the top surfaces of the substrate 102 and the isolation structures 104.

Next, in some embodiments, the gate dielectric layer 110P and the gate electrode layer 112P in the gate trench 926 are etched back to expose the nanostructures 106N (the semiconductor layers 908B). In some embodiments, portions of the gate dielectric layer 110P and gate electrode layer 112P that are wrapped around the nanostructures 106N are removed by one or more etching processes. The etching processes may be selective etching processes that selectively etch the gate dielectric layer 110P and the gate electrode layer 112P, with minimal etching (or substantially no etching) of the nanostructures 106N, the gate spacers 114, and the inner spacers 116. The selective etching process may be a dry etching process, a wet etching process, other suitable etching process, or combinations thereof. In some embodiments, after the etching processes, the top surface of the gate electrode layer 112P is lower than the bottommost surfaces of the nanostructures 106N.

Then, in some embodiments, the gate dielectric layer 110N and the gate electrode layer 112N are formed in the gate trench 926 and over the gate dielectric layer 110P and the gate electrode layer 112P to wrap around the nanostructures 106N (the semiconductor layers 908B). In some embodiments, the gate dielectric layer 110N wraps around each of the nanostructures 106N, and the gate electrode layer 112N wraps around the gate dielectric layer 110N and each of the nanostructures 106N. Moreover, the gate dielectric layer 110N is also formed on the sidewalls of the inner spacers 116 and the gate spacers 114, as well as over the top surface of the gate electrode layer 112P. In some embodiments, the gate dielectric layer 110N is further in contact with the gate dielectric layer 110P, as shown in FIG. 21A. Therefore, the gate dielectric layer 110P, the gate electrode layer 112P, the gate dielectric layer 110N, and the gate electrode layer 112N may be together referred to as the gate structure 108 to replace the dummy gate structure 914.

In some embodiments, the gate dielectric layers 110P and 110N may include oxide with nitrogen doped dielectric material (initial layer) combined with metal content high-k dielectric material (e.g., k value (dielectric constant)>7.9). For example, the gate dielectric layers 110P and 110N may include hafnium oxide (HfO₂), which has a dielectric constant in a range from about 18 to about 40. Alternatively, the gate dielectric layers 110P and 110N may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO3 (STO), BaTiO₃ (BTO), BaZrO, HfLaO, HfSiO, LaSiO, AlSiO, HfTaO, HfTiO, (Ba, Sr) TiO₃ (BST), Al₂O₃, Si₃N₄, oxynitrides (SiON), other suitable materials, or combinations thereof. The gate dielectric layers 110P and 110N may be formed by chemical oxidation, thermal oxidation, CVD, physical vapor deposition (PVD), ALD, high-density plasma CVD (HDPCVD), MOCVD, RPCVD, PECVD, LPCVD, atomic layer CVD (ALCVD), atmospheric pressure CVD (APCVD), flowable CVD (FCVD), other suitable methods, or combinations thereof.

In some embodiments, the gate electrode layer 112P may include one or more p-type work function metal layers for PFETs 100P, and the gate electrode layer 112N may include one or more n-type work function metal layers for NFETs 100N. In other embodiments, the gate electrode layer 112P and the gate electrode layer 112N may include the same work function metal layer.

In some embodiments, the n-type and p-type work function metal layers may include a material such as such as W, Al, Cu, TIN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the n-type and p-type work function metal layers may be deposited utilizing CVD, PVD, ALD, HDPCVD, MOCVD, RPCVD, PECVD, LPCVD, ALCVD, APCVD, FCVD, or the like. However, any suitable materials and processes may be utilized to form the n-type work function metal layer and the p-type work function metal layer.

In some embodiments, each of the gate electrode layers 112P and 112N may include a single layer or alternatively a multi-layer structure. In some embodiments, each of the gate electrode layers 112P and 112N may include a capping layer, a barrier layer, and a fill material (not shown). The capping layer may be formed adjacent to the gate dielectric layers 110P and 110N, and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed adjacent to the capping layer, and may be formed of a different material than the capping layer. For example, the barrier layer may be formed of one or more layers of a metallic material such as TIN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

In some embodiments, the fill material may include a suitable conductive material, such as Al, W, and/or Cu. In some embodiments, the capping layer, the barrier layer, and the fill material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

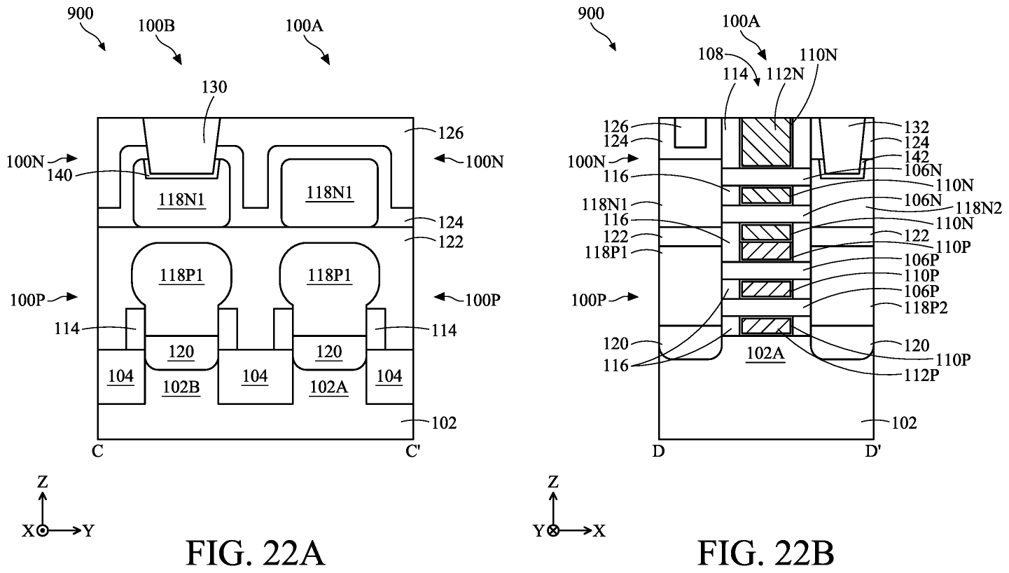

Referring to FIGS. 22A and 22B, the source/drain contacts 130 and 132 and the corresponding silicide layers 140 and 142 are formed on the frontside of the workpiece 900, in accordance with some embodiments. In some embodiments, contact openings are formed to pass through the ILD layer 126, the CESLs 124, and portions of the source/drain features 118N, so as to expose the source/drain features 118N. In some embodiments, one or more photolithography and etching processes are performed to etch the ILD layer 126, the CESLs 124, and the source/drain features 118N, so as to form the contact openings that exposes the source/drain features 118N.

Next, in some embodiments, the silicide layers 140 and 142 are formed on the exposed surfaces of the source/drain features 118N in the contact openings. In some embodiments, the silicide layers 140 and 142 are formed by depositing metal layers on the source/drain features 118N, and heating the workpiece 900 to cause constituents of the source/drain features 118N to react with metal constituents of the metal layers. Then, in some embodiments, a conductive material is deposited in the contact openings and on the silicide layers 140 and 142 by a deposition process, so as to form the source/drain contacts 130 and 132. That is, the contact openings are filled with the conductive material to form the source/drain contacts 130 and 132.

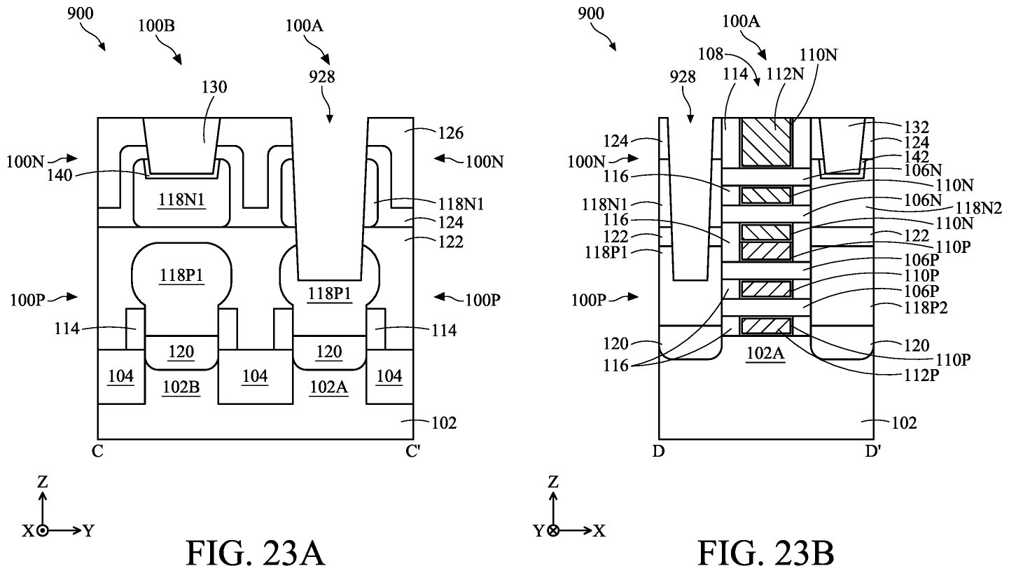

Referring to FIGS. 23A and 23B, a trench 928 is formed on the frontside of the workpiece 900 to expose both the source/drain features 118N and 118P, in accordance with some embodiments. In some embodiments, the trench 928 is formed to pass through the ILD layer 126, the CESLs 124, the source/drain feature 118N, the ILD layer 122, and portions of the source/drain features 118P, so as to expose the source/drain features 118N and 118P. In some embodiments, one or more photolithography and etching processes are performed to etch the ILD layer 126, the CESLs 124, the source/drain feature 118N, and the ILD layer 122, and partially etch the source/drain feature 118P, so as to form the trench 928 that exposes the source/drain features 118N and 118P. In some embodiments, the trench 928 exposes the source/drain features 118N1 and 118P1 of the CFET 100A, as shown in FIGS. 23A and 23B.

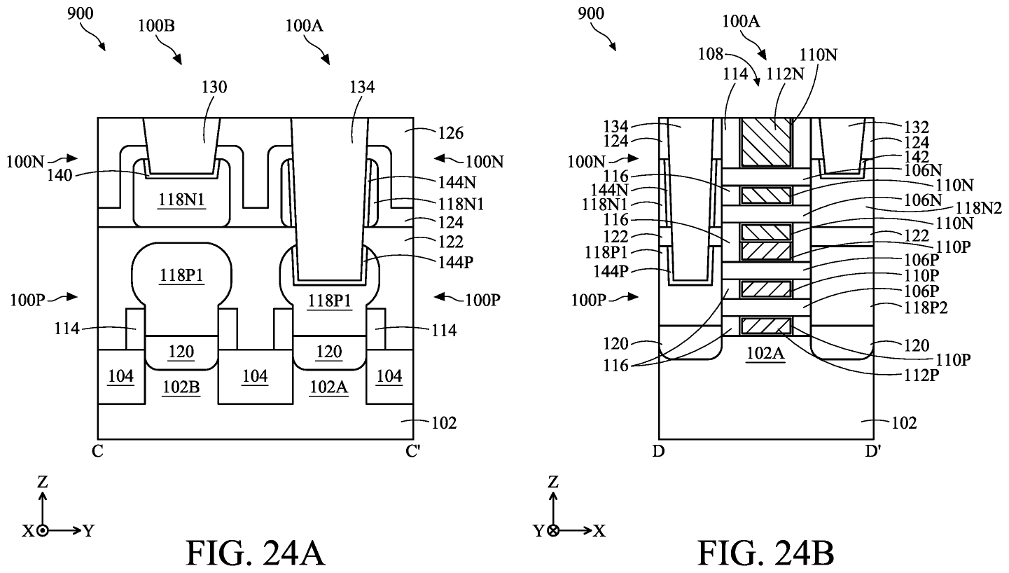

Referring to FIGS. 24A and 24B, the source/drain contact 134 and the corresponding silicide layers 144N and 144P are formed on the frontside of the workpiece 900, in accordance with some embodiments. In some embodiments, the silicide layers 144N and 144P are formed on the exposed surfaces of the source/drain features 118N and 118P in the trench 928, respectively. In some embodiments, the silicide layers 144N and 144P are formed by depositing metal layers on the source/drain features 118N and 118P, and heating the workpiece 900 to cause constituents of the source/drain features 118N and 118P to react with metal constituents of the metal layers. In some embodiments, the silicide layers 144N and 144P may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the material of the silicide layer 144N is different from the material of the silicide layer 144P. For example, the silicide layer 144N may include a compound with metal(s) and Si, and the silicide layer 144P may include a compound with metal(s), Si, and Ge.

Then, in some embodiments, a conductive material is deposited in the trench 928 and on the silicide layers 144N and 144P by a deposition process, so as to form the source/drain contact 134. That is, the trench 928 is filled with the conductive material to form the source/drain contact 134. In some embodiments, the source/drain contact 134 is in contact with and electrically connected to the source/drain features 118N1 and 118P1 of the CFET 100A, as shown in FIGS. 24A and 24B. In some embodiments, the silicide layer 144N is formed on sidewalls of a portion of the source/drain contact 134 inside the source/drain feature 118N1 of the CFET 100A, and the silicide layer 144P is formed on sidewalls and the bottom surface of a portion of the source/drain contact 134 inside the source/drain feature 118P1 of the CFET 100A, as shown in FIGS. 24A and 24B.

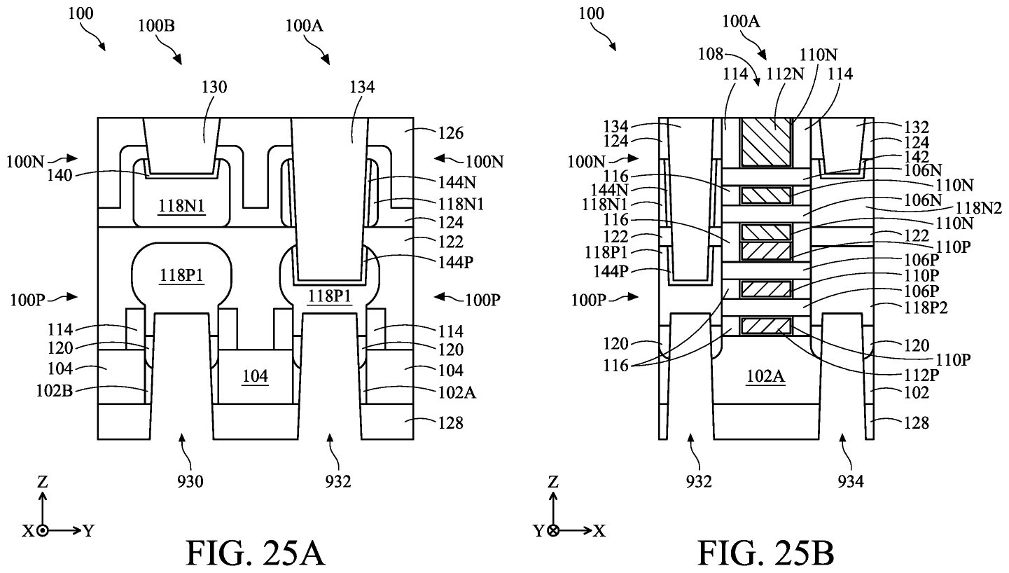

Referring to FIGS. 25A and 25B, a portion of the substrate 102 is removed from the backside of the workpiece 900, and the ILD layer 128 is formed on backside surface of the substrate 102, in accordance with some embodiments. In other words, the substrate is thinned and the ILD layer 128 is formed under and in contact with the thinned substrate 102. Before thinning the substrate 102 and forming the ILD layer 128, the workpiece 900 may be flipped. For the purpose of simplicity, the sequent figures are shown without being flipped. In some embodiments, a carrier wafer may be bonded to the frontside of the workpiece 900 before flipping. In some embodiments, the substrate 102 is thinned (or partially removed) by a selective etching process or a CMP process.

After thinning the substrate 102, the ILD layer 128 may be formed under the thinned substrate 102, as shown in FIGS. 25A and 25B. In some embodiments, the ILD layer 128 may include TEOS formed oxide, un-doped silicate glass, or doped silicon oxide such as BPSG, FSG, PSG, BSG, low-k dielectric materials, other suitable dielectric materials, or combinations thereof. The ILD layer 128 may be formed by CVD, PVD, ALD, HDPCVD, MOCVD, RPCVD, PECVD, LPCVD, ALCVD, APCVD, FCVD, or other suitable methods.

Still referring to FIGS. 25A and 25B, trenches 930, 932, and 934 are formed on the backside of the workpiece 900 to expose both the source/drain features 118P, in accordance with some embodiments. In some embodiments, the trenches 930, 932, and 934 are formed to pass through the ILD layer 128, the substrate 102, the bottom isolation layers 120, and portions of the source/drain features 118P, so as to expose the source/drain features 118P. In some embodiments, one or more photolithography and etching processes are performed to etch the ILD layer 128, the substrate 102, and the bottom isolation layers 120, and partially etch the source/drain features 118P, so as to form the trenches 930, 932, and 934 that expose the source/drain features 118P. In some embodiments, the trench 930 exposes the source/drain feature 118P1 of the CFET 100B, the trench 932 exposes the source/drain feature 118P1 of the CFET 100A, and the trench 934 exposes the source/drain feature 118P2 of the CFET 100A, as shown in FIGS. 25A and 25B.

Referring back to FIGS. 1A and 1B, the source/drain contacts 136, 137, 138 and the corresponding silicide layers 146, 147, 148 are formed on the backside of the workpiece 900, in accordance with some embodiments. In these embodiments, the resultant device of the workpiece 900 may be fabricated to as the semiconductor device 100 shown in FIGS. 1A and 1B. In some embodiments, the silicide layers 146, 147, and 148 are formed on the exposed surfaces of the source/drain features 118P in the trenches 930, 932, and 934, respectively. In some embodiments, the silicide layers 146, 147, and 148 are formed by depositing metal layers on the source/drain features 118P, and heating the workpiece 900 to cause constituents of the source/drain features 118P to react with metal constituents of the metal layers. Then, in some embodiments, a conductive material is deposited in the trenches 930, 932, and 934 and on the silicide layers 146, 147, and 148 by a deposition process, so as to form the source/drain contacts 136, 137, and 138. That is, the trenches 930, 932, and 934 are filled with the conductive material to form the source/drain contacts 136, 137, and 138.

In some embodiments, the source/drain contact 137 is in contact with and electrically connected to the source/drain feature 118P1 of the CFET 100A, and the silicide layer 147 is formed on sidewalls and the top surface of a portion of the source/drain contact 137 inside the source/drain feature 118P1 of the CFET 100A, as shown in FIGS. 1A and 1B.

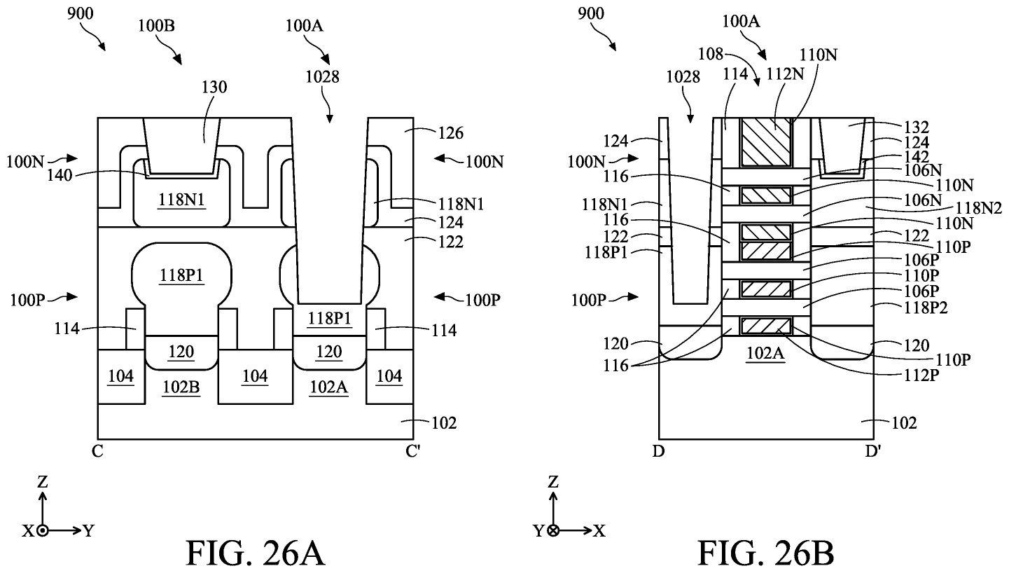

Referring to FIGS. 26A and 26B, the fabrication stage shown in FIGS. 26A and 26B follows the fabrication stage shown in FIGS. 22A and 22B. In some embodiments, a trench 1028 is formed to pass through the ILD layer 126, the CESLs 124, the source/drain feature 118N, the ILD layer 122, and portions of the source/drain features 118P, so as to expose the source/drain features 118N and 118P. In some embodiments, one or more photolithography and etching processes are performed to etch the ILD layer 126, the CESLs 124, the ILD layer 122, the source/drain features 118N and 118P, so as to form the trench 1028 that exposes the source/drain features 118N and 118P. In some embodiments, the trench 1028 exposes the source/drain features 118N1 and 118P1 of the CFET 100A, as shown in FIGS. 26A and 26B. In some embodiments, in the source/drain feature 118P1 of the CFET 100A, the trench 1028 extends downward more than the trench 928. That is, the trench 1028 is deeper than the trench 928 in the Z-direction.

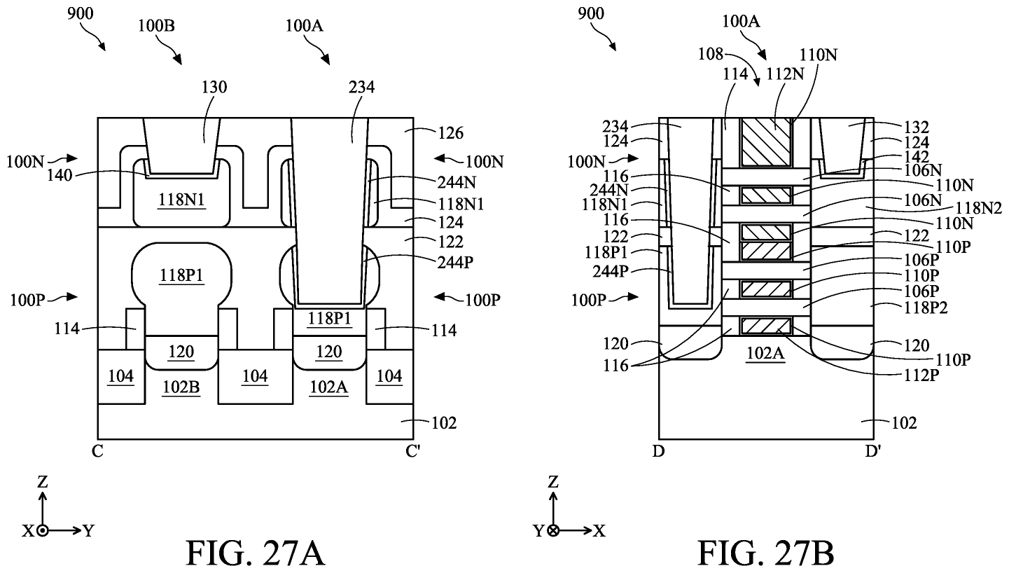

Referring to FIGS. 27A and 27B, the source/drain contact 234 and the corresponding silicide layers 244N and 244P are formed on the frontside of the workpiece 900, in accordance with some embodiments. In some embodiments, the silicide layers 244N and 244P are formed on the exposed surfaces of the source/drain features 118N and 118P in the contact openings, respectively. In some embodiments, the materials and methods used in forming the silicide layers 244N and 244P are the same as or similar to those of the silicide layers 144N and 144P, and are not repeated herein. In some embodiments, the material of the silicide layer 244N is different from the material of the silicide layer 244P.

Then, in some embodiments, a conductive material is deposited in the trench 1028 and on the silicide layers 244N and 244P by a deposition process, so as to form the source/drain contact 234. That is, the trench 1028 is filled with the conductive material to form the source/drain contact 234. In some embodiments, the source/drain contact 234 is in contact with and electrically connected to the source/drain features 118N1 and 118P1 of the CFET 100A, as shown in FIGS. 27A and 27B. In some embodiments, the silicide layer 244N is formed on sidewalls of a portion of the source/drain contact 234 inside the source/drain feature 118N1 of the CFET 100A, and the silicide layer 244P is formed on sidewalls and the bottom surface of a portion of the source/drain contact 234 inside the source/drain feature 118P1 of the CFET 100A, as shown in FIGS. 27A and 27B.

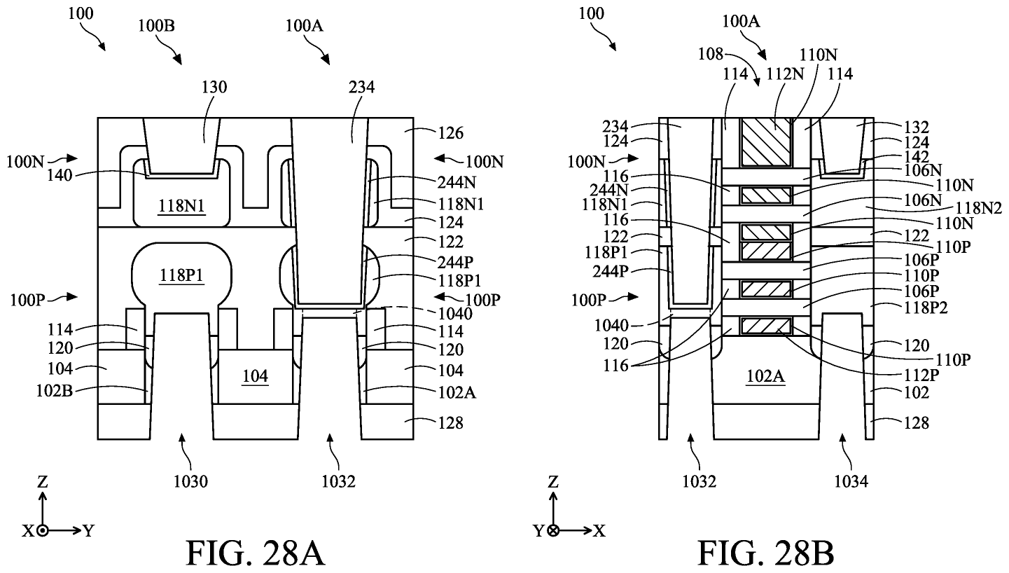

Referring to FIGS. 28A and 28B, the ILD layer 128 is formed on backside surface of the substrate 102, in accordance with some embodiments. The material and method used in forming the ILD layer 128 has been discussed above with reference to FIGS. 25A and 25B, and are not repeated herein.

Still referring to FIGS. 28A and 28B, trenches 1030, 1032, and 1034 are formed on the backside of the workpiece 900 to expose both the source/drain features 118P, in accordance with some embodiments. In some embodiments, the trenches 1030, 1032, and 1034 are formed to pass through the ILD layer 128, the substrate 102, the bottom isolation layers 120, and portions of the source/drain features 118P, so as to expose the source/drain features 118P. In some embodiments, one or more photolithography and etching processes are performed to etch the ILD layer 128, the substrate 102, and the bottom isolation layers 120, and partially etch the source/drain features 118P, so as to form the trenches 1030, 1032, and 1034 that expose the source/drain features 118P. In some embodiments, the trench 1030 exposes the source/drain feature 118P1 of the CFET 100B, the trench 1032 exposes the source/drain feature 118P1 of the CFET 100A, and the trench 1034 exposes the source/drain feature 118P2 of the CFET 100A, as shown in FIGS. 28A and 28B.

In some embodiments, the remaining portion 1040 of the source/drain feature 118P1 of the CFET 100A is left between the silicide layer 244P and the trench 1032. That is, the remaining portion 1040 is left after forming the trench 1032, and it separates the top surface of the trench 1032 from the bottom surface of the silicide layer 244P, as shown in FIGS. 28A and 28B. In some embodiments, the thickness of the remaining portion 1040 has been configured to make the remaining portion 1040 be completely converted into silicide during the subsequent fabrication stage.

Referring back to FIGS. 2A and 2B, the source/drain contacts 136, 237, 138 and the corresponding silicide layers 146, 247, 148 are formed on the backside of the workpiece 900, in accordance with some embodiments. In these embodiments, the resultant device of the workpiece 900 may be fabricated to as the semiconductor device 200 shown in FIGS. 2A and 2B. In some embodiments, the silicide layers 146, 247, and 148 are formed on the exposed surfaces of the source/drain features 118P in the trenches 1030, 1032, and 1034, respectively. In some embodiments, the material and method used in forming the silicide layer 247 are the same as or similar to those of the silicide layer 147, and are not repeated herein.

In some embodiments, the source/drain contact 237 is in contact with and electrically connected to the source/drain feature 118P1 of the CFET 100A, and the silicide layer 247 is formed on sidewalls and the top surface of a portion of the source/drain contact 137 inside the source/drain feature 118P1 of the CFET 100A, as shown in FIGS. 2A and 2B. In some embodiments, the remaining portion 1040 of the source/drain feature 118P1 of the CFET 100A is completely converted into the silicide layer 247 during the silicide process of the silicide layer 247. That is, after forming the silicide layer 247, the silicide layer 247 is in direct contact with the silicide layer 244P without material of the source/drain feature 118P1 of the CFET 100A locating between the silicide layers 247 and 244P, as shown in FIGS. 2A and 2B. In these embodiments, a horizontal portion of the silicide layer 244P formed on the bottom surface of the source/drain contact 234 is in direct contact with a horizontal portion of the silicide layer 247 formed on the top surface of the source/drain contact 237 in the source/drain feature 118P1 of the CFET 100A.

In some embodiments, the thickness of the remaining portion 1040 can be controlled by adjusting the depth of the trench 1028 in the Z-direction. In other embodiments, the thickness of the remaining portion 1040 can be controlled by adjusting the depth of the trench 1032 in the Z-direction. In certain embodiments, the thickness of the remaining portion 1040 can be controlled by simultaneously adjusting the depths of the trenches 1028 and 1032 in the Z-direction.

In some embodiments, the resultant device of the workpiece 900 may be fabricated to as the semiconductor device 300 shown in FIGS. 3A and 3B. In these embodiments, in order to form the silicide layer 344P and the source/drain contact 337 that are in direct contact, the trench 1028 may extend downward more in the Z-direction and/or the trench 1032 may extend upward more in the Z-direction. As a result, the silicide layer 344P (formed in a manner similar to the silicide layer 244P) on the source/drain contact 334 formed in the trench 1028 may be exposed in the trench 1032. In this way, after forming the silicide layer 347 and the source/drain contact 337 in the trench 1032, since the silicide layer 347 cannot be formed on the silicide layer 344P, the source/drain contact 337 is in direct contact with the silicide layer 344P. That is, a horizontal portion of the silicide layer 344P formed on the bottom surface of the source/drain contact 334 is in direct contact with the top surface of the source/drain contact 337 in the source/drain feature 118P1 of the CFET 100A, as shown in FIGS. 3A and 3B.

In some embodiments, the resultant device of the workpiece 900 may be fabricated to as the semiconductor device 400 shown in FIGS. 4A and 4B. In these embodiments, in order to form the source/drain contacts 434 and 437 that are in direct contact, the trench 1028 may extend downward more in the Z-direction and/or the trench 1032 may extend upward more in the Z-direction, and the formation of the trench 1032 may further include removing a portion of the silicide layer 444P (formed in a manner similar to the silicide layer 244P) formed on the source/drain contact 434. As a result, the bottom surface of the source/drain contact 334 formed in the trench 1028 may be exposed in the trench 1032. In this way, after forming the silicide layer 447 and the source/drain contact 437 in the trench 1032, since the silicide layer 447 cannot be formed on the source/drain contact 434, the source/drain contact 437 is in direct contact with the source/drain contact 434. That is, the bottom surface of the source/drain contact 434 is in direct contact with the top surface of the source/drain contact 437 in the source/drain feature 118P1 of the CFET 100A, as shown in FIGS. 4A and 4B.

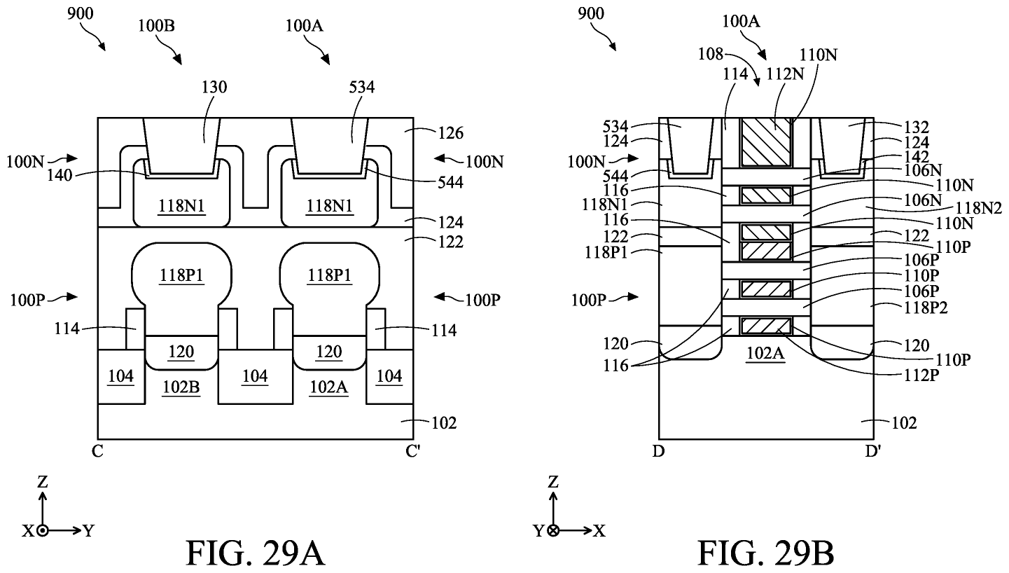

Referring to FIGS. 29A and 29B, the fabrication stage shown in FIGS. 29A and 29B follows the fabrication stage shown in FIGS. 21A and 21B. In some embodiments, the source/drain contacts 130, 534, and 132 and the corresponding silicide layers 140, 544, and 142 are formed on the frontside of the workpiece 900. In some embodiments, one or more photolithography and etching processes are performed to etch the ILD layer 126, the CESLs 124, and the source/drain features 118N, so as to form the contact openings that exposes the source/drain features 118N.

Next, in some embodiments, the silicide layers 140, 544, and 142 and the source/drain contacts 130, 534, and 132 are formed in the contact openings. In some embodiments, the materials and methods used in forming the silicide layer 544 and the source/drain contact 534 are the same as or similar to those of the silicide layers 140, 142 and the source/drain contacts 130, 132, and are not repeated herein. In some embodiments, the source/drain contact 534 is in contact with and electrically connected to the source/drain feature 118N1 of the CFET 100A, and the silicide layer 544 is formed on sidewalls and bottom surface of a portion of the source/drain contact 534 inside the source/drain feature 118P1 of the CFET 100A, as shown in FIGS. 29A and 29B.

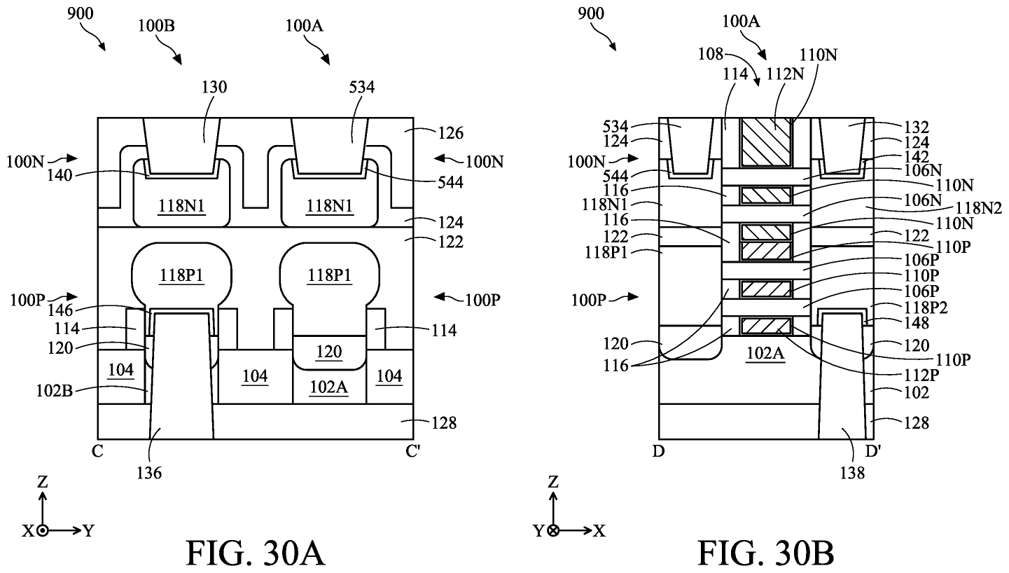

Referring to FIGS. 30A and 30B, the ILD layer 128 is formed on backside surface of the substrate 102, in accordance with some embodiments. The material and method used in forming the ILD layer 128 has been discussed above with reference to FIGS. 25A and 25B, and are not repeated herein.

Still referring to FIGS. 30A and 30B, the source/drain contacts 136 and 138 and the corresponding silicide layers 146 and 148 are formed on the backside of the workpiece 900, in accordance with some embodiments. The materials and methods used in forming the source/drain contacts 136 and 138 and the silicide layers 146 and 148 have been discussed above with reference to FIGS. 1A, 1B, 25A and 25B, and are not repeated herein.

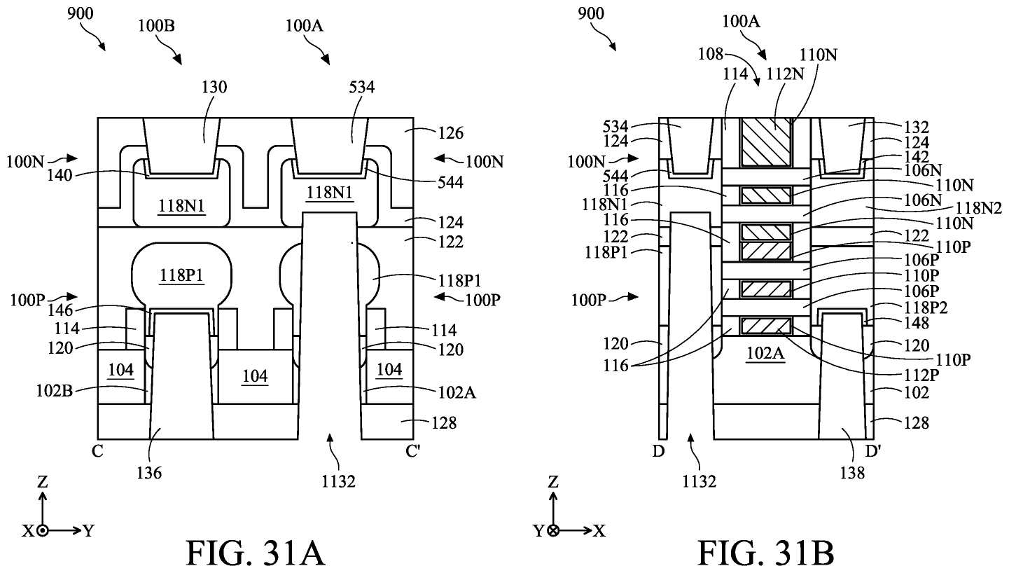

Referring to FIGS. 31A and 31B, a trench 1132 is formed on the backside of the workpiece 900 to expose both of the source/drain features 118N and 118P, in accordance with some embodiments. In some embodiments, the trench 1132 is formed to pass through the ILD layer 128, the substrate 102, the bottom isolation layer 120, the source/drain feature 118P, the ILD layer 122, and portions of the source/drain features 118N, so as to expose the source/drain features 118N and 118P. In some embodiments, one or more photolithography and etching processes are performed to etch the ILD layer 128, the substrate 102, the bottom isolation layer 120, the source/drain feature 118P, and the ILD layer 122, and partially etch the source/drain feature 118N, so as to form the trench 1132 that exposes the source/drain features 118N and 118P. In some embodiments, the trench 1132 exposes the source/drain features 118N1 and 118P1 of the CFET 100A, as shown in FIGS. 31A and 31B.

Referring back to FIGS. 5A and 5B, the source/drain contact 537 and the corresponding silicide layers 547N and 547P are formed on the backside of the workpiece 900, in accordance with some embodiments. In some embodiments, the silicide layers 547N and 547P are formed on the exposed surfaces of the source/drain features 118N and 118P in the trench 1132, respectively. In some embodiments, the materials and methods used in forming the silicide layers 547N and 547P are the same as or similar to those of the silicide layers 144N and 144P, and are not repeated herein. In some embodiments, the material of the silicide layer 547N is different from the material of the silicide layer 547P. In some embodiments, the material of the silicide layer 544 is different from the materials of the silicide layers 547N and 547P.

Then, in some embodiments, a conductive material is deposited in the trench 1132 and on the silicide layers 547N and 547P by a deposition process, so as to form the source/drain contact 537. That is, the trench 1132 is filled with the conductive material to form the source/drain contact 537. In some embodiments, the source/drain contact 537 is in contact with and electrically connected to the source/drain features 118N1 and 118P1 of the CFET 100A, as shown in FIGS. 5A and 5B. In some embodiments, the silicide layer 547N is formed on sidewalls and the top surface of a portion of the source/drain contact 537 inside the source/drain feature 118N1 of the CFET 100A, and the silicide layer 547P is formed on sidewalls of a portion of the source/drain contact 537 inside the source/drain feature 118P1 of the CFET 100A, as shown in FIGS. 5A and 5B.

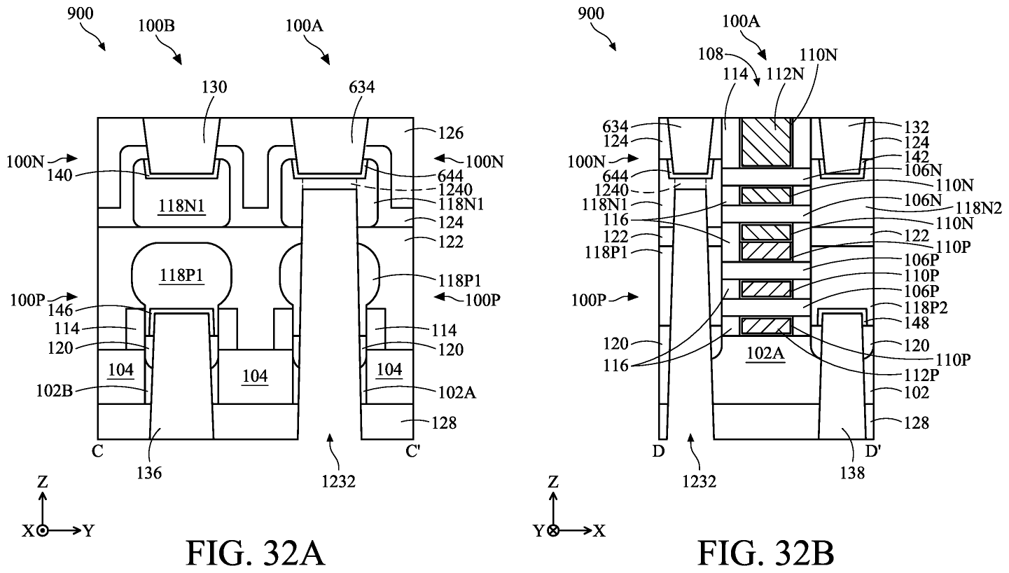

Referring to FIGS. 32A and 32B, the fabrication stage shown in FIGS. 32A and 32B follows the fabrication stage shown in FIGS. 30A and 30B. For the purpose of clarity, in FIGS. 32A and 32B, the source/drain contact 534 and the silicide layer 544 shown in FIGS. 30A and 30B are replaced by the source/drain contact 634 and the silicide layer 644, respectively. In some embodiments, a trench 1232 is formed to pass through the ILD layer 128, the substrate 102, the bottom isolation layer 120, the source/drain feature 118P, the ILD layer 122, and portions of the source/drain features 118N, so as to expose the source/drain features 118N and 118P, so as to expose the source/drain features 118N and 118P. In some embodiments, one or more photolithography and etching processes are performed to etch the ILD layer 128, the substrate 102, the bottom isolation layer 120, the source/drain feature 118P, and the ILD layer 122, and partially etch the source/drain feature 118N, so as to form the trench 1232 that exposes the source/drain features 118N and 118P. In some embodiments, the trench 1232 exposes the source/drain features 118N1 and 118P1 of the CFET 100A, as shown in FIGS. 32A and 32B. In some embodiments, in the source/drain feature 118N1 of the CFET 100A, the trench 1232 extends upward more than the trench 1132. That is, the trench 1232 is deeper than the trench 1132 in the Z-direction.

In some embodiments, the remaining portion 1240 of the source/drain feature 118N1 of the CFET 100A is left between the silicide layer 644 and the trench 1232. That is, the remaining portion 1240 is left after forming the trench 1232, and it separates the top surface of the trench 1232 from the bottom surface of the silicide layer 644, as shown in FIGS. 32A and 32B. In some embodiments, the thickness of the remaining portion 1240 has been configured to make the remaining portion 1240 be completely converted into silicide during the subsequent fabrication stage.

Referring back to FIGS. 6A and 6B, the source/drain contact 637 and the corresponding silicide layers 647N and 647P are formed on the backside of the workpiece 900, in accordance with some embodiments. In these embodiments, the resultant device of the workpiece 900 may be fabricated to as the semiconductor device 600 shown in FIGS. 6A and 6B. In some embodiments, the silicide layers 647N and 647P are formed on the exposed surfaces of the source/drain features 118N and 118P in the trench 1232, respectively. In some embodiments, the material and method used in forming the silicide layers 647N and 647P are the same as or similar to those of the silicide layers 144N and 144P, and are not repeated herein.

Then, in some embodiments, a conductive material is deposited in the trench 1232 and on the silicide layers 647N and 647P by a deposition process, so as to form the source/drain contact 637. That is, the trench 1232 is filled with the conductive material to form the source/drain contact 637. In some embodiments, the source/drain contact 637 is in contact with and electrically connected to the source/drain features 118N1 and 118P1 of the CFET 100A. In some embodiments, the silicide layer 647N is formed on sidewalls and the top surface of a portion of the source/drain contact 637 inside the source/drain feature 118N1 of the CFET 100A, and the silicide layer 647P is formed on sidewalls of a portion of the source/drain contact 637 inside the source/drain feature 118P1 of the CFET 100A, as shown in FIGS. 6A and 6B. In some embodiments, the remaining portion 1240 of the source/drain feature 118N1 of the CFET 100A is completely converted into the silicide layer 647N during the silicide process of the silicide layer 647N. That is, after forming the silicide layer 647N, the silicide layer 647N is in direct contact with the silicide layer 644 without material of the source/drain feature 118N1 of the CFET 100A locating between the silicide layers 647N and 644, as shown in FIGS. 6A and 6B. In these embodiments, in the source/drain feature 118N1 of the CFET 100A, a horizontal portion of the silicide layer 644 formed on the bottom surface of the source/drain contact 634 is in direct contact with a horizontal portion of the silicide layer 647N formed on the top surface of the source/drain contact 637.

In some embodiments, the thickness of the remaining portion 1240 can be controlled by adjusting the depth of the trench for forming the source/drain contact 634 in the Z-direction. In other embodiments, the thickness of the remaining portion 1240 can be controlled by adjusting the depth of the trench 1232 in the Z-direction. In certain embodiments, the thickness of the remaining portion 1240 can be controlled by simultaneously adjusting the depths of the trench 1232 and the trench for forming the source/drain contact 634 in the Z-direction.

In some embodiments, the resultant device of the workpiece 900 may be fabricated to as the semiconductor device 700 shown in FIGS. 7A and 7B. In these embodiments, in order to form the silicide layer 744 and the source/drain contact 737 that are in direct contact, the trench for forming the source/drain contact 734 may extend downward more in the Z-direction and/or the trench 1232 may extend upward more in the Z-direction. As a result, the silicide layer 744 (formed in a manner similar to the silicide layer 544) on the source/drain contact 734 may be exposed in the trench 1232. In this way, after forming the silicide layers 747N and 747P and the source/drain contact 737 in the trench 1232, since the silicide layer 747N cannot be formed on the silicide layer 744, the source/drain contact 737 is in direct contact with the silicide layer 744. That is, a horizontal portion of the silicide layer 744 formed on the bottom surface of the source/drain contact 734 is in direct contact with the top surface of the source/drain contact 737 in the source/drain feature 118N1 of the CFET 100A, as shown in FIGS. 7A and 7B.

In some embodiments, the resultant device of the workpiece 900 may be fabricated to as the semiconductor device 800 shown in FIGS. 8A and 8B. In these embodiments, in order to form the source/drain contacts 834 and 837 that are in direct contact, the trench for forming the source/drain contact 834 may extend downward more in the Z-direction and/or the trench 1232 may extend upward more in the Z-direction, and the formation of the trench 1232 may further include removing a portion of the silicide layer 844 (formed in a manner similar to the silicide layer 544) formed on the source/drain contact 834. As a result, the bottom surface of the source/drain contact 834 may be exposed in the trench 1232. In this way, after forming the silicide layers 847N and 847P and the source/drain contact 837 in the trench 1232, since the silicide layer 847N cannot be formed on the source/drain contact 834, the source/drain contact 837 is in direct contact with the source/drain contact 834. That is, the bottom surface of the source/drain contact 834 is in direct contact with the top surface of the source/drain contact 837 in the source/drain feature 118N1 of the CFET 100A, as shown in FIGS. 8A and 8B.

The source/drain contacts 130, 132, 134, 136, 137, 138, 234, 237, 334, 337, 434, 437, 534, 537, 634, 637, 734, 737, 834, and 837 may each include the conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. In some embodiments, the source/drain contacts 130, 132, 134, 136, 137, 138, 234, 237, 334, 337, 434, 437, 534, 537, 634, 637, 734, 737, 834, and 837 may each include a single conductive material layer or multiple conductive layers.

In some embodiments, the source/drain contacts 130, 132, 134, 136, 137, 138, 234, 237, 334, 337, 434, 437, 534, 537, 634, 637, 734, 737, 834, and 837 may each include a sidewall dielectric layer formed on the sidewalls. The sidewall dielectric layer may be used to improve the isolation between the source/drain contacts and surrounding components. In some embodiments, the material of the sidewall dielectric layer may include silicon nitride (Si₃N₄), silicon oxide (SiO₂), SiC, SiOC, SiON, SiCN, SiOCN, high-k dielectrics, other suitable materials, or combinations thereof. In some embodiments, the sidewall dielectric layer 250 may be deposited by CVD, PVD, ALD, HDPCVD, MOCVD, RPCVD, PECVD, LPCVD, ALCVD, APCVD, other suitable methods, or combinations thereof.

In some embodiments, the workpiece 900 may further include a dielectric gate structure to isolate the CFET device (e.g., CFETs 100A and 100B discussed above) from other devices. For example, the dielectric gate structure may be formed in a non-functional channel region adjacent to the CFET device. In some embodiments, one dielectric gate structure is formed on right side or left side of the CFET 100A in the X-direction, alternatively, two dielectric gate structures are formed on opposite sides of the CFET 100A in the X-direction. In some embodiments, the material of the dielectric gate structure may include silicon nitride (Si₃N₄), silicon oxide (SiO₂), SiC, SiOC, SION, SiCN, SiOCN, high-k dielectrics, other suitable materials, or combinations thereof. In some embodiments, the dielectric gate structure may be deposited by CVD, PVD, ALD, HDPCVD, MOCVD, RPCVD, PECVD, LPCVD, ALCVD, APCVD, other suitable methods, or combinations thereof.

The embodiments disclosed herein relate to semiconductor structures and their forming methods, and more particularly to methods and semiconductor structures that include forming a frontside S/D LI contact and a corresponding backside S/D contact in a CFET device. In this way, signals could be transmitted between the frontside S/D LI contact and the backside S/D contact. As a result, the signal routing can be arranged on the frontside, the backside of the device, or on both the frontside and the backside of the device. Therefore, the flexibility for the signal routing is provided. Similarly, alternative embodiments discussed herein include forming a frontside S/D contact and a corresponding backside S/D LI contact in a CFET device. It also provides flexibility for the signal routing. On the other hand, the embodiments provided by the present disclosure are not limited to the signal routing, they can further be applied to any device having a S/D LI contact to provide the flexibility for the routing of the interconnection structure.

In one exemplary aspect, the present disclosure is directed to a semiconductor structure. The semiconductor structure includes a first transistor and a second transistor vertically overlapping the first transistor. The first transistor includes first nanostructures that are spaced apart from each other in a Z-direction, and a first source/drain feature and a second source/drain feature attached to opposite sides of the first nanostructures in an X-direction. The second transistor includes second nanostructures vertically overlapping the first nanostructures, wherein the second nanostructures are spaced apart from each other in the Z-direction; and a third source/drain feature and a fourth source/drain feature, attached to opposite sides of the second nanostructures in the X-direction and vertically overlapping the first source/drain feature and the second source/drain feature, respectively. The semiconductor structure further includes a gate structure that is wrapped around the first nanostructures and the second nanostructures. The semiconductor structure further includes a first source/drain contact, extending through the third source/drain feature and partially extending into the first source/drain feature; and a second source/drain contact extending into the first source/drain feature.

In another exemplary aspect, the present disclosure is directed to a semiconductor structure. The semiconductor structure includes a first transistor and a second transistor over the first transistor. The first transistor includes first nanostructures that are over a substrate and spaced apart from each other in a Z-direction, and a first source/drain feature and a second source/drain feature attached to opposite sides of the first nanostructures in an X-direction. The second transistor includes second nanostructures that are over the first nanostructures and spaced apart from each other in the Z-direction; and a third source/drain feature and a fourth source/drain feature, attached to opposite sides of the second nanostructures in the X-direction and over the first source/drain feature and the second source/drain feature, respectively. The semiconductor structure further includes a gate structure that is wrapped around the first nanostructures and the second nanostructures. The semiconductor structure further includes a first source/drain contact partially extending into the third source/drain feature; and a second source/drain contact, extending through the substrate and the first source/drain feature and partially extending into the third source/drain feature.

In yet another exemplary aspect, the present disclosure is directed to a method of forming a semiconductor structure. The method includes forming a fin structure extending in an X-direction over a substrate, wherein the fin structure includes first semiconductor layers and second semiconductor layers alternately stacked in a Z-direction; forming a dummy gate structure over the fin structure and extending in a Y-direction; and forming a first source/drain feature and a second source/drain feature on opposite sides of the dummy gate structure in the X-direction, wherein the first source/drain feature and the second source/drain feature are attached to a first group of the second semiconductor layers. The method further includes forming a third source/drain feature and a fourth source/drain feature over the first source/drain feature and the second source/drain feature, respectively, wherein the third source/drain feature and the fourth source/drain feature are attached to a second group of the second semiconductor layers; forming a first trench extending through the third source/drain feature and partially extending into the first source/drain feature; and filling the first trench with a first conductive material to form a first source/drain contact. The method further includes forming a second trench extending through the substrate and partially extending into the first source/drain feature; and filling the second trench with a second conductive material to form a second source/drain contact.

In yet another exemplary aspect, the present disclosure is directed to a semiconductor structure. The semiconductor structure includes a first transistor and a second transistor over the first transistor. The first transistor includes first nanostructures over a substrate, wherein the first nanostructures are spaced apart from each other in a Z-direction, and a first source/drain feature and a second source/drain feature attached to opposite sides of the first nanostructures in an X-direction. The second transistor includes second nanostructures over the first nanostructures, wherein the second nanostructures are spaced apart from each other in the Z-direction; and a third source/drain feature and a fourth source/drain feature, attached to opposite sides of the second nanostructures in the X-direction and over the first source/drain feature and the second source/drain feature, respectively. The semiconductor structure further includes a contact etch stop layer over the third source/drain feature and the fourth source/drain feature, and a first interlayer dielectric (ILD) layer over the contact etch stop layer. The semiconductor structure further includes a first source/drain contact, extending through the first ILD layer, the contact etch stop layer, and the third source/drain feature, and partially extending into the first source/drain feature; and a second source/drain contact, extending through the substrate and partially extending into the first source/drain feature.

In some embodiments, the semiconductor structure further includes a first silicide layer, formed on an interface between the first source/drain contact and the first source/drain feature; and a second silicide layer, formed on an interface between the second source/drain contact and the first source/drain feature.

In some embodiments, a horizontal portion of the first silicide layer formed on a bottom surface of the first source/drain contact is in direct contact with a horizontal portion of the second silicide layer formed on a top surface of the second source/drain contact.

In some embodiments, a horizontal portion of the first silicide layer formed on a bottom surface of the first source/drain contact is in direct contact with a top surface of the second source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor, comprising:
first nanostructures, wherein the first nanostructures are spaced apart from each other in a Z-direction; and
a first source/drain feature and a second source/drain feature, attached to opposite sides of the first nanostructures in an X-direction;
a second transistor vertically overlapping the first transistor, wherein the second transistor comprises:
second nanostructures vertically overlapping the first nanostructures, wherein the second nanostructures are spaced apart from each other in the Z-direction; and
a third source/drain feature and a fourth source/drain feature, attached to opposite sides of the second nanostructures in the X-direction and vertically overlapping the first source/drain feature and the second source/drain feature, respectively;
a gate structure wrapped around the first nanostructures and the second nanostructures;
a first source/drain contact, extending through the third source/drain feature and partially extending into the first source/drain feature; and
a second source/drain contact extending into the first source/drain feature.

2. The semiconductor structure of claim 1, further comprising:
a first interlayer dielectric (ILD) layer, surrounding the first source/drain feature and the second source/drain feature, and separating the first source/drain feature and the second source/drain feature from the third source/drain feature and the fourth source/drain feature,
wherein the first source/drain contact further extends through the first ILD layer.

3. The semiconductor structure of claim 1, further comprising:
a first silicide layer, formed on an interface between the first source/drain contact and the third source/drain feature; and
a second silicide layer, formed on an interface between the first source/drain contact and the first source/drain feature.

4. The semiconductor structure of claim 3, further comprising:
a third silicide layer, formed on an interface between the second source/drain contact and the first source/drain feature.

5. The semiconductor structure of claim 4, wherein a horizontal portion of the second silicide layer formed on a bottom surface of the first source/drain contact is separated from a horizontal portion of the third silicide layer formed on a top surface of the second source/drain contact by a portion of the first source/drain feature.

6. The semiconductor structure of claim 4, wherein a horizontal portion of the second silicide layer formed on a bottom surface of the first source/drain contact is in direct contact with a horizontal portion of the third silicide layer formed on a top surface of the second source/drain contact.

7. The semiconductor structure of claim 4, wherein a horizontal portion of the second silicide layer formed on a bottom surface of the first source/drain contact is in direct contact with a top surface of the second source/drain contact.

8. The semiconductor structure of claim 4, wherein a bottom surface of the first source/drain contact is in direct contact with a top surface of the second source/drain contact.

9. A semiconductor structure, comprising:
a first transistor, comprising:
first nanostructures over a substrate, wherein the first nanostructures are spaced apart from each other in a Z-direction; and
a first source/drain feature and a second source/drain feature, attached to opposite sides of the first nanostructures in an X-direction;
a second transistor over the first transistor, wherein the second transistor comprises:
second nanostructures over the first nanostructures, wherein the second nanostructures are spaced apart from each other in the Z-direction; and
a third source/drain feature and a fourth source/drain feature, attached to opposite sides of the second nanostructures in the X-direction and being over the first source/drain feature and the second source/drain feature, respectively;
a gate structure wrapped around the first nanostructures and the second nanostructures;
a first source/drain contact, partially extending into the third source/drain feature; and
a second source/drain contact, extending through the substrate and the first source/drain feature, and partially extending into the third source/drain feature.

10. The semiconductor structure of claim 9, further comprising:
a first interlayer dielectric (ILD) layer, formed on a backside of the substrate,
wherein the second source/drain contact further extends through the first ILD layer.

11. The semiconductor structure of claim 9, further comprising:
a first silicide layer, formed on an interface between the first source/drain contact and the third source/drain feature.

12. The semiconductor structure of claim 11, further comprising:
a second silicide layer, formed on an interface between the second source/drain contact and the first source/drain feature; and
a third silicide layer, formed on an interface between the second source/drain contact and the third source/drain feature.

13. The semiconductor structure of claim 12, wherein a horizontal portion of the first silicide layer formed on a bottom surface of the first source/drain contact is separated from a horizontal portion of the third silicide layer formed on a top surface of the second source/drain contact by a portion of the third source/drain feature.

14. The semiconductor structure of claim 12, wherein a horizontal portion of the first silicide layer formed on a bottom surface of the first source/drain contact is in direct contact with a horizontal portion of the third silicide layer formed on a top surface of the second source/drain contact.

15. The semiconductor structure of claim 12, wherein a horizontal portion of the first silicide layer formed on a bottom surface of the first source/drain contact is in direct contact with a top surface of the second source/drain contact.

16. The semiconductor structure of claim 12, wherein a bottom surface of the first source/drain contact is in direct contact with a top surface of the second source/drain contact.

17. A method of forming semiconductor structure, comprising:
forming a fin structure extending in an X-direction over a substrate, wherein the fin structure comprises first semiconductor layers and second semiconductor layers alternately stacked in a Z-direction;
forming a dummy gate structure over the fin structure and extending in a Y-direction;
forming a first source/drain feature and a second source/drain feature on opposite sides of the dummy gate structure in the X-direction, wherein the first source/drain feature and the second source/drain feature are attached to a first group of the second semiconductor layers;
forming a third source/drain feature and a fourth source/drain feature over the first source/drain feature and the second source/drain feature, respectively, wherein the third source/drain feature and the fourth source/drain feature are attached to a second group of the second semiconductor layers;
forming a first trench extending through the third source/drain feature and partially extending into the first source/drain feature;
filling the first trench with a first conductive material to form a first source/drain contact;
forming a second trench extending through the substrate and partially extending into the first source/drain feature; and
filling the second trench with a second conductive material to form a second source/drain contact.

18. The method of claim 17, further comprising:
before filling the first trench with the first conductive material, forming a first silicide layer on a surface of the first source/drain feature exposed by the first trench; and
before filling the second trench with the second conductive material, forming a second silicide layer on a surface of the third source/drain feature exposed by the first trench.

19. The method of claim 18, wherein the forming the second trench comprises:
etching through the substrate and partially etching the first source/drain feature to form the second trench,
wherein after forming the second trench, a remaining portion of the first source/drain feature remains and separates a top surface of the second trench from a horizontal portion of the first silicide layer formed on a bottom surface of the first source/drain contact.

20. The method of claim 19, further comprising:
forming a third silicide layer on a surface of the first source/drain feature exposed by the second trench,
wherein the forming the third silicide layer converts the remaining portion of the first source/drain feature into a horizontal portion of the third silicide layer formed on the top surface of the second trench, such that the horizontal portion of the third silicide layer formed on the top surface of the second trench is in direct contact with the horizontal portion of the first silicide layer formed on the bottom surface of the first source/drain contact.
